(19) United States
(12) Patent Application Publication
(10) Pub. No.: US 2025/0333842 A1
(43) Pub. Date: Oct. 30, 2025

(54) CHEMICAL VAPOR INFILTRATION OF AGGREGATED SCAFFOLDING MATERIALS TO PRODUCE COMPOSITE PARTICULATE MATERIALS

(71) Applicant: Group14 Technologies, Inc., Woodinville, WA (US)

(72) Inventors: Rajankumar Patel, Lehi, UT (US); Henry R. Costantino, Woodinville, WA (US); Avery J. Sakshaug, Snohomish, WA (US); Christopher Timmons, Monroe, WA (US); Luke Barney, Bothell, WA (US)

(21) Appl. No.: 19/189,861

(22) Filed: Apr. 25, 2025

Related U.S. Application Data
(60) Provisional application No. 63/639,533, filed on Apr. 26, 2024.

(51) Int. Cl. C23C 16/44; C23C 16/24

(52) U.S. Cl. CPC C23C 16/4417; C23C 16/24

(57) ABSTRACT

Silicon-carbon composite materials and related processes that overcome the challenges for providing amorphous nano-sized silicon entrained within porous carbon. Agglomerated porous carbon is used during a composite creation process.

### CROSS-REFERENCE TO RELATED APPLICATION

This application claims the benefit of priority to U.S. Provisional Application No. 63/639,533, filed Apr. 26, 2024, the entire contents of which is incorporated herein by reference.

### BACKGROUND

### Technical Field

The present invention generally relates to methods of manufacturing silicon-carbon composite materials with properties that overcome the challenges for providing amorphous nano-sized silicon entrained within porous carbon.

### Description of the Related Art

Chemical vapor infiltration (CVI is a process wherein a gaseous substrate reacts within a porous scaffold material. This approach can be employed to produce composite materials, for instance silicon-carbon composites, wherein a silicon-containing gas decomposes at elevated temperature within a porous carbon scaffold. An exemplary prior art process is shown in FIG. 1. While this approach can be employed to manufacture a variety of composite materials, there is particular interest in silicon-carbon (Si—C) composite materials. Such Si—C composite materials have utility, for example as energy storage materials, for example as an anode material for batteries, such as lithium-ion batteries (LIBs). LIBs have potential to replace devices currently used in any number of applications. For example, current lead acid automobile batteries are not adequate for next generation all-electric and hybrid electric vehicles due to irreversible, stable sulfate formations during discharge. Lithium-ion batteries are a viable alternative to the lead-based systems currently used due to their capacity, and other considerations.

To this end, there is continued strong interest in developing new LIB anode materials, particularly silicon, which has 10-fold higher gravimetric capacity than conventional graphite. However, silicon exhibits large volume change during cycling, in turn leading to electrode deterioration and solid-electrolyte interphase (SEI) instability. The most common amelioration approach is to reduce silicon particle size, for instance Dv50<150 nm, for instance Dv50<100 nm, for instance Dv50<50 nm, for instance Dv50<20 nm, for instance Dv50<10 nm, for instance Dv50<5 nm, for instance Dv50<2 nm, either as discrete particles or within a matrix. Thus far, techniques for creating nano-scale silicon involve high-temperature reduction of silicon oxide, extensive particle diminution, multi-step toxic etching, and/or other cost prohibitive processes. Likewise, common matrix approaches involve expensive materials such as graphene or nano-graphite, and/or require complex processing and coating.

It is known from scientific literature that non-graphitizable (hard) carbon is beneficial as a LIB anode material (Liu Y, Xue, J S, Zheng T, Dahn, J R. Carbon 1996, 34:193-200; Wu, Y P, Fang, SB, Jiang, Y Y. 1998, 75:201-206; Buiel E, Dahn J R. Electrochim Acta 1999 45:121-130). The basis for this improved performance stems from the disordered nature of the graphene layers that allows Li-ions to intercalate on either side of the graphene plane allowing for theoretically double the stoichiometric content of Li ions versus crystalline graphite. Furthermore, the disordered structure improves the rate capability of the material by allowing Li ions to intercalate isotropically as opposed to graphite where lithiation can only proceed in parallel to the stacked graphene planes. Despite these desirable electrochemical properties, amorphous carbons have not seen wide-spread deployment in commercial Li-ion batteries, owing primarily to low first cycle efficiency (FCE) and low bulk density (<1 g/cc). Instead, amorphous carbon has been used more commonly as a low-mass additive and coating for other active material components of the battery to improve conductivity and reduce surface side reactions.

In recent years, amorphous carbon as a LIB battery material has received considerable attention as a coating for silicon anode materials. Such a silicon-carbon core-shell structure has the potential for not only improving conductivity, but also buffering the expansion of silicon as it lithiates, thus stabilizing its cycle stability and minimizing problems associated with particle pulverization, isolation, and solid electrolyte interphase (SEI) integrity (Jung, Y, Lee K, Oh, S. Electrochim Acta 2007 52:7061-7067; Zuo P, Yin G, Ma Y. Electrochim Acta 2007 52:4878-4883; Ng S H, Wang J, Wexler D, Chew S Y, Liu H K. J Phys Chem C 2007 111:11131-11138). Problems associated with this strategy include the lack of a suitable silicon starting material that is amenable to the coating process, and the inherent lack of engineered void space within the carbon-coated silicon core-shell composite particle to accommodate expansion of the silicon during lithiation. This inevitably leads to cycle stability failure due to destruction of core-shell structure and SEI layer (Beattie S D, Larcher D, Morcrette M, Simon B, Tarascon, J-M. J Electrochem Soc 2008 155:A 158-A 163).

An alternative to core shell structure is a structure wherein amorphous, nano-sized silicon is homogeneously distributed within the porosity of a porous carbon scaffold. The porous carbon allows for desirable properties: (i) carbon porosity provides void volume to accommodate the expansion of silicon during lithiation thus reducing the net composite particle expansion at the electrode level; (ii) the disordered graphene network provides increased electrical conductivity to the silicon thus enabling faster charge/discharge rates, (iii) nano-pore structure acts as a template for the synthesis of silicon thereby dictating its size, distribution, and morphology.

To this end, the desired inverse hierarchical structure can be achieved by employing CVI wherein a silicon-containing gas can completely permeate nanoporous carbon and decompose therein to nano-sized silicon. The CVI approach confers several advantages in terms of silicon structure. One advantage is that nanoporous carbon provides nucleation sites for growing silicon while dictating maximum particle shape and size. Confining the growth of silicon within a nano-porous structure affords reduced susceptibility to cracking or pulverization and loss of contact caused by expansion. Moreover, this structure promotes nano-sized silicon to remain as amorphous phase. This property provides the opportunity for high charge/discharge rates, particularly in combination with silicon's vicinity within the conductive carbon scaffold. This system provides a high-rate-capable, solid-state lithium diffusion pathway that directly delivers lithium-ions to the nano-scale silicon interface. Another benefit of the silicon provided via CVI within the carbon scaffold is the inhibition of formation of undesirable crystalline Li₁₅Si₄ phase. Y et another benefit is that the CVI process provides for void space within the particle interior.

In order to quantitate the percentage loading of silicon within the silicon-carbon composite, thermogravimetric analysis (TGA) may be employed. For this purpose, the silicon-composite is heated from 25° C. to 1100° C., which, without being bound by theory, provides for burn off of all carbon, and oxidation of all silicon to SiO₂. Thus, the % silicon comprising the silicon-carbon composite is calculated as

$$\% Si = 100 \times [ [ M 1100 \times ( 28 / ( 28 + ( 16 \times 2 ) ) ) ] / M ° ]$$

wherein M 1100 is the mass of the silicon-carbon composite at 1100° C. and M° is the minimum mass of the silicon-carbon composite between 30° C. and 200° C. when the silicon-carbon composite is heated under air from about 25° C. to about 1100° C., as determined by TGA.

In order to gauge relative amount of silicon impregnated into the porosity of the porous carbon, TGA may be employed. TGA is used to assess the fraction of silicon residing within the porosity of porous carbon relative to the total silicon present, i.e., sum of silicon within the porosity and on the particle surface. As the silicon-carbon composite is heated under air, the sample exhibits a mass increase that initiates at about 300° C. to 500° C. that reflects initial oxidation of silicon to SiO₂, and then the sample exhibits a mass loss as the carbon is burned off, and then the sample exhibits mass increase reflecting resumed conversion of silicon into SiO₂ which increases towards an asymptotic value as the temperature approaches 1100° C. as silicon oxidizes to completion. For the purposes of this analysis, it is assumed that the minimum mass recorded for the sample as it is heated from 800° C. to 1100° C. represents the point at which carbon burnoff is complete. Any further mass increase beyond that point corresponds to the oxidation of silicon to SiO₂ and that the total mass at completion of oxidation is SiO₂. Thus, the percentage of unoxidized silicon after carbon burnoff as a proportion of the total amount of silicon can be determined using the formula:

$$Z = 1 \text{.875} \times [ ( M 1100 - M ) / M 1100 ] \times 100$$

where M 1100 is the mass of the sample at completion of oxidation at a temperature of 1100° C., and M is the minimum mass recorded for the sample as it is heated from 800° C. to 1100° C.

Without being bound by theory, the temperature at which silicon is oxidized under TGA conditions relates to the length scale of the oxide coating on the silicon due to the diffusion of oxygen atoms through the oxide layer. Thus, silicon residing within the carbon porosity will oxidize at a lower temperature than deposits of silicon on a particle surface due to the necessarily thinner coating existing on these surfaces. In this fashion, calculation of Z is used to quantitatively assess the fraction of silicon not impregnated within the porosity of the porous carbon scaffold.

Previous approaches to solving the problem of impregnating amorphous, nano-sized silicon within the pores of a porous scaffold employed materials comprised using scaffolding particles with volume average particle size (Dv50) of less than 1 mm, in order to accommodate infiltration of the silicon precursor gas, for example silane, into the pores of the porous particles, and, according to the elevated temperature of the silicon precursor gas and/or porous particles, decomposition of the silicon precursor gas within the pores of the porous particles to yield a particulate composite material. However, processing of scaffold particles with such relatively low particle size via the CVI reaction poses challenges in material handling, elutriation, and harvesting, as well as imposes limitations on CVI reactor designs.

### BRIEF SUMMARY

A process for preparing silicon-carbon composite particles includes providing a porous carbon material comprising a pore volume, wherein the pore volume includes greater than 70% microporosity, agglomerating the porous carbon material with an agglomerant to produce an agglomerated carbon material, heating the agglomerated carbon material to a temperature from 350° C. to 550° C., and contacting the agglomerated carbon material with a silane feedstock gas to produce the silicon-carbon composite particles.

In accordance with an aspect of the disclosed embodiments, a system for producing silicon-carbon composite particles that includes an agglomerating device configured to agglomerate activated porous carbon material with an agglomerant to produce an agglomerated carbon material and a kiln configured to heat the agglomerated carbon material to a temperature from 350° C. to 550° C. while introducing a silane feedstock gas to perform a chemical vapor infiltration process that produces silicon-carbon composite particles.

A key outcome in this regard is to achieve the desired form of silicon in the desired form, namely amorphous nano-sized silicon. Furthermore, another key outcome is to achieve the silicon impregnation within the pores of the porous carbon. Y et another key outcome is to achieve high utilization of the silicon-containing gas, i.e., achieve a high fraction of the silicon introduced into a variety of CVI reactors that impregnate the silicon into the pores of the porous carbon in the form of amorphous nano-sized silicon. Such manufacturing processes and materials produced therefore, for example, silicon-carbon composite materials, have utility as anode materials for energy storage devices, for example lithium-ion batteries.

### BRIEF DESCRIPTION OF THE DRAWINGS

FIG. 1 is a prior art process for creating a composite.

FIG. 2 is a block diagram of an exemplary system for creating composite materials in accordance with embodiments disclosed herein.

FIG. 3 is an exemplary process performed by the system of FIG. 2 in accordance with an embodiment disclosed herein.

FIG. 4 is an exemplary process performed by the system of FIG. 2 in accordance with an embodiment disclosed herein.

FIG. 5 is an exemplary process for agglomerated carbon creation for use in the process of FIG. 3.

FIG. 6 is an exemplary process for agglomerated carbon creation for use in the process of FIG. 3.

FIG. 7 is an exemplary process for agglomerated carbon creation for use in the process of FIG. 3.

FIG. 8 is an exemplary process for agglomerated carbon creation for use in the process of FIG. 3.

FIG. 9 is an exemplary process for agglomerated carbon creation for use in the process of FIG. 3.

FIG. 10 is a perspective view of an exemplary agglomerated carbon material.

FIG. 11 is a cross-sectional view of the agglomerated carbon material.

FIG. 12 is a cross-sectional view of a particle of the agglomerated carbon material.

FIG. 13 is an exemplary process for post agglomerated carbon creation for use in the process of FIG. 3.

FIG. 14 illustrates diffusion-limited CVI of a carbon particle;

FIG. 15 illustrates a non-diffusion-limited CVI when using agglomerated carbon particles.

FIG. 16 is a graph showing a relationship between Z and average Coulombic efficiency for various silicon-carbon composite materials.

FIG. 17 is a graph showing a differential capacity vs voltage plot for silicon-carbon composite 3 from 2nd cycle using a half-cell.

FIG. 18 is a graph showing a differential capacity vs voltage plot for silicon-carbon composite 3 from 2nd cycle to 5th cycle using a half-cell.

FIG. 19 is a graph showing a dQ/dV vs V plot for various silicon-carbon composite materials.

FIG. 20 is a graph showing an example calculation of φ for silicon-carbon composite 3.

FIG. 21 is a graph showing a Z vs q plot for various silicon-carbon composite materials.

FIG. 22 is a graph showing a Y_{CV1} vs X_{Si} plot for various silicon-carbon composite materials.

FIG. 23 is a graph illustrating silane utilization (%) as determined from Fourier-transformed infrared spectroscopy (FTIR) as a function on run time for the preparation of sample 21.

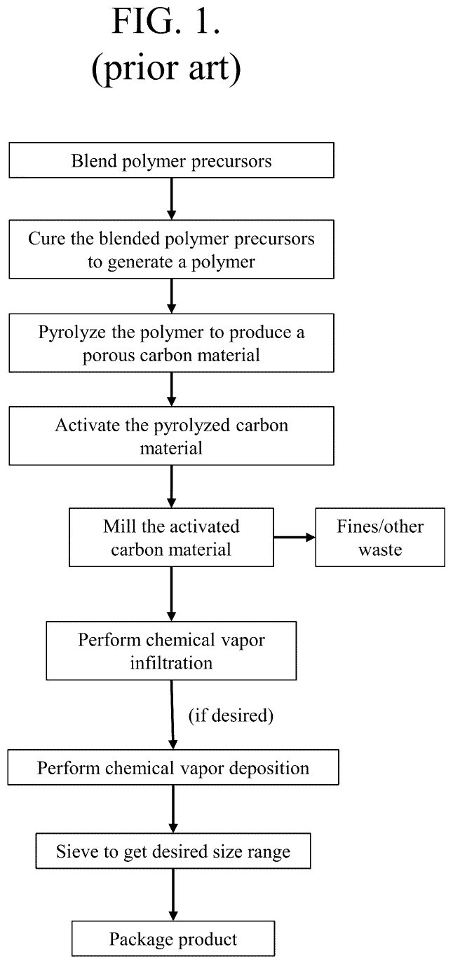

### DETAILED DESCRIPTION

In the following description, certain specific details are set forth in order to provide a thorough understanding of various embodiments. However, one skilled in the art will understand that the invention may be practiced without these details. In other instances, well-known structures have not been shown or described in detail to avoid unnecessarily obscuring descriptions of the embodiments. Unless the context requires otherwise, throughout the specification and claims which follow, the word “comprise” and variations thereof, such as, “comprises” and “comprising” are to be construed in an open, inclusive sense, that is, as “including, but not limited to.” Further, headings provided herein are for convenience only and do not interpret the scope or meaning of the claimed invention.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. Also, as used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

In various embodiments, scaffolding particles are processed not as primary particles, but rather as agglomerates of scaffolding particles. The Dv50 of the agglomerates is greater than Dv50 for the scaffolding particles, for example greater than 1 mm. By processing the scaffolding material in an agglomerated form, the challenges of handling, elutriation, and harvesting can be overcome, and limitations in CVI reactor designs can likewise be overcome.

In various embodiments, suitable porous scaffolds include, but are not limited to, porous carbon scaffolds, for example carbon having a pore volume comprising micropores (less than 2 nm), mesopores (2 to 50 nm), and/or macropores (greater than 50 nm). Suitable precursors for the carbon scaffold include, but are not limited to, sugars and polyols, organic acids, phenolic compounds, cross-linkers, and amine compounds. Suitable compositing materials include, but are not limited to, silicon materials. Precursors for the silicon include, but are not limited to, silicon containing gases such as silane, high-order silanes (such as di-, tri-, and/or tetrasilane), and/or chlorosilane(s) (such as mono-, di-, tri-, and tetrachlorosilane) and mixtures thereof. Chemical vapor infiltration (CVI) of silicon into the pores of porous scaffold materials within the agglomerate is accomplished by exposing said agglomerates to silicon-containing gas (e.g., silane) at elevated temperatures. This produces amorphous nano-sized silicon. Furthermore, silicon is impregnated within the pores of the porous carbon. High utilization of the silicon-containing gas is achieved, i.e., achieve a high fraction of the silicon introduced into the CVI reactor that converts into silicon impregnated into the pores of the porous carbon in the form of amorphous nano-sized silicon. Such manufacturing processes and materials produced therefore, for example, silicon-carbon composite materials, have utility as anode materials for energy storage devices, for example lithium-ion batteries.

In various embodiments, porous carbon is formed into a pelletized and/or agglomerated form. An electrochemical modifier is grown in pores of the pelletized and/or agglomerated porous carbon by a chemical vapor infiltration (CVI) process. The result improves yield because carbon fines (i.e., particle size <1μ) are minimal due to agglomerating the fines before the CVI processing.

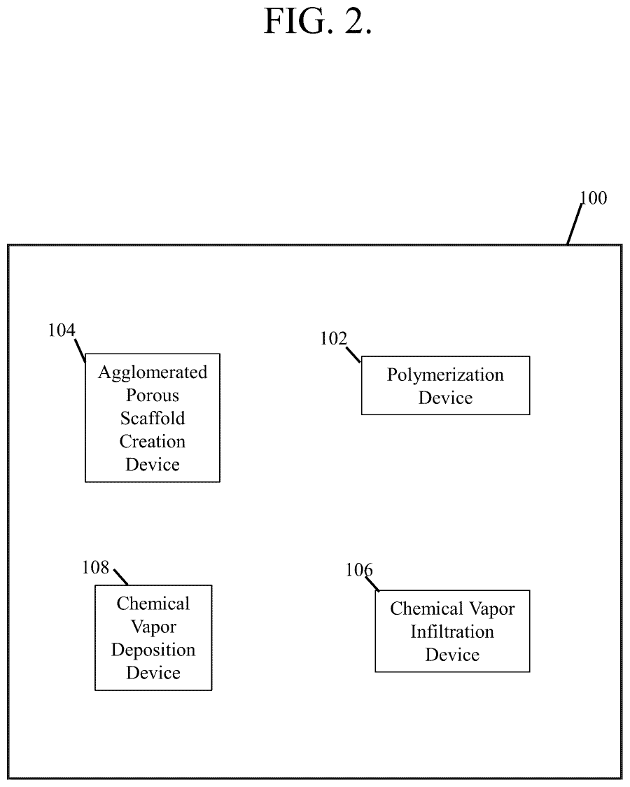

Referring to FIG. 2, an exemplary system 100 produces a composite material from an agglomerated base material. The system 100 may include a polymerization device 102, an agglomerated porous material creation device 104 and a chemical vapor infiltration device 106. The system 100 may optionally include a chemical vapor deposition device 108. The system 100 and components may include other material processing components, such as, without limitation, hoppers, milling devices, sieves, packaging devices, separators, etc.

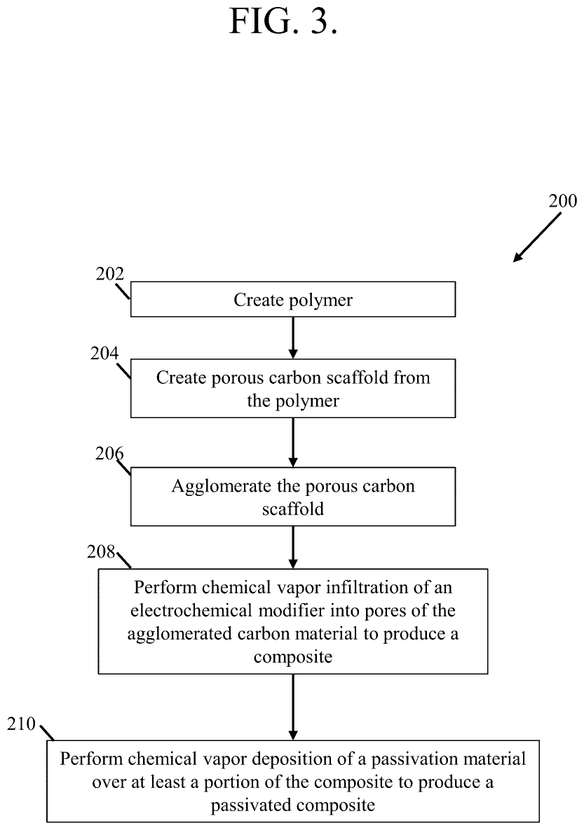

Referring to FIG. 3, an exemplary process 200 performed by the system 100 of FIG. 2 for creating a silicon carbon composite material using pelletized and/or agglomerated carbon is shown. At a block 202, a polymer is created, as described in more detail below. At a block 204, a porous carbon material is created from the polymer, as described in more detail below. At a block 206, the porous carbon material is agglomerated. Various agglomerated material creation processes are described below. At a block 208, CVI is performed for infiltrating an electrochemical modifier into pores of the agglomerated porous carbon material to produce a composite. Exemplary CVI processing devices (i.e., kilns, reactors) are described below. At a block 210, chemical vapor deposition (CVD) of a passivation material (e.g., decomposed hydrocarbon or the like) is optionally performed over at least a portion of the composite to produce a passivated silicon-carbon composite. The process 200 can greatly improve yield and allow for the use of less costly/sophisticated equipment (such as kilns/reactors).

Details of the process 200 and variations thereof are shown and described below.

### 1. Porous Scaffold Materials

In various embodiments, a porous scaffold may be used, into which silicon is to be impregnated. In this context, the porous scaffold can comprise various materials. In some embodiments the porous scaffold material primarily includes carbon, for example hard carbon. Other allotropes of carbon are also envisioned in other embodiments, for example, graphite, amorphous carbon, diamond, C60, carbon nanotubes (e.g., single and/or multi-walled), graphene and/or carbon fibers. The introduction of porosity into the carbon material can be achieved by a variety of means. For instance, the porosity in the carbon material can be achieved by modulation of polymer precursors, and/or processing conditions to create said porous carbon material and described in detail in the subsequent section.

In other embodiments, the porous scaffold includes a polymer material. To this end, a wide variety of polymers are envisioned in various embodiments to have utility, including, but not limited to, inorganic polymer, organic polymers, and addition polymers. Examples of inorganic polymers in this context includes, but are not limited to, homochain polymers of silicon-silicon such as polysilanes, silicon carbide, polygermanes, and polystannanes. Additional examples of inorganic polymers include, but are not limited to, heterochain polymers such as polyborazylenes, polysiloxanes like polydimethylsiloxane (PDMS), polymethylhydrosiloxane (PMHS) and polydiphenylsiloxane, polysilazanes like perhydridopolysilazane (PHPS), polyphosphazenes and poly(dichlorophosphazenes), polyphosphates, polythiazyls, and polysulfides. Examples of organic polymers includes, but are not limited to, low density polyethylene (LDPE), high density polyethylene (HDPE), polypropylene (PP), polyvinyl chloride (PVC), polystyrene (PS), nylon, nylon 6, nylon 6,6, teflon (Polytetrafluoroethylene), thermoplastic polyurethanes (TPU), polyureas, poly(lactide), poly(glycolide) and combinations thereof, phenolic resins, polyamides, polyaramids, polyethylene terephthalate, polychloroprene, polyacrylonitrile, polyaniline, polyimide, poly(3,4-ethylenedioxythiophene) polystyrene sulfonate (PDOT:PSS), and others known in the arts. The organic polymer can be synthetic or natural in origin. In some embodiments, the polymer is a polysaccharide, such as starch, cellulose, cellobiose, amylose, amylpectin, gum Arabic, lignin, and the like. In some embodiments, the polysaccharide is derived from the carmelization of mono- or oligomeric sugars, such as fructose, glucose, sucrose, maltose, raffinose, and the like.

In certain embodiments, the porous scaffold polymer material includes a coordination polymer. Coordination polymers in this context include, but are not limited to, metal organic frameworks (MOFs). Techniques for production of MOFs, as well as exemplary species of MOFs, are known and described in the art (“The Chemistry and Applications of Metal-Organic Frameworks, Hiroyasu Furukawa et al. Science 341, (2013); DOI: 10.1126/science.1230444). Examples of MOFs in the context include, but are not limited to, Basolite™ materials and zeolitic imidazolate frameworks (ZIFs).

Concomitant with the myriad variety of polymers envisioned with the potential to provide a porous substrate, various processing approaches are envisioned in various embodiments to achieve said porosity. In this context, general methods for imparting porosity into various materials are myriad, as known in the art, including, but certainly not limited to, methods involving emulsification, micelle creation, gasification, dissolution followed by solvent removal (for example, lyophilization), axial compaction and sintering, gravity sintering, powder rolling and sintering, isostatic compaction and sintering, metal spraying, metal coating and sintering, metal injection molding and sintering, and the like. Other approaches to create a porous polymeric material, including creation of a porous gel, such as a freeze dried gel, aerogel, and the like are also envisioned.

In certain embodiments, the porous scaffold material includes a porous ceramic material. In certain embodiments, the porous scaffold material includes a porous ceramic foam. In this context, general methods for imparting porosity into ceramic materials are varied, as known in the art, including, but certainly not limited to, creation of porous In this context, general methods and materials suitable for comprising the porous ceramic include, but are not limited to, porous aluminum oxide, porous zirconia toughened alumina, porous partially stabilized zirconia, porous alumina, porous sintered silicon carbide, sintered silicon nitride, porous cordierite, porous zirconium oxide, clay-bound silicon carbide, and the like.

In certain embodiments, the porous scaffold includes porous silica or other silicon material containing oxygen. The creation of silicon gels, including sol gels, and other porous silica materials is known in the art.

In certain embodiments, the porous material includes a porous metal. Suitable metals in this regard include, but are not limited to porous aluminum, porous steel, porous nickel, porous Inconcel, porous Hasteloy, porous titanium, porous copper, porous brass, porous gold, porous silver, porous germanium, and other metals capable of being formed into porous structures, as known in the art. In some embodiments, the porous scaffold material includes a porous metal foam. The types of metals and methods to manufacture related to same are known in the art. Such methods include, but are not limited to, casting (including foaming, infiltration, and lost-foam casting), deposition (chemical and physical), gas-eutectic formation, and powder metallurgy techniques (such as powder sintering, compaction in the presence of a foaming agent, and fiber metallurgy techniques).

### 2. Porous Carbon Scaffold

Methods for preparing porous carbon materials from polymer precursors are known in the art. For example, methods for preparation of carbon materials are described in U.S. Pat. Nos. 7,723,262, 8,293,818, 8,404,384, 8,654,507, 8,916,296, 9,269,502, 10,590,277, and U.S. patent application Ser. No. 16/745,197, the full disclosures of which are hereby incorporated by reference in their entireties for all purposes.

Accordingly, in one embodiment the present disclosure provides a method for preparing any of the carbon materials or polymer gels described above. The carbon materials may be synthesized through pyrolysis of either a single precursor, for example a saccharide material such as sucrose, fructose, glucose, dextrin, maltodextrin, starch, amylopectin, amlyose, lignin, gum Arabic, and other saccharides known in the art, and combinations thereof. Alternatively, the carbon materials may be synthesized through pyrolysis of a complex resin, for instance formed using a sol-gel method using polymer precursors such as phenol, resorcinol, bisphenol A, urea, melamine, and other suitable compounds known in the art, and combinations thereof, in a suitable solvent such as water, ethanol, methanol, and other solvents known in the art, and combinations thereof, with cross-linking agents such as formaldehyde, hexamethylenetetramine, furfural, and other cross-lining agents known in the art, and combinations thereof. The resin may be acid or basic and may contain a catalyst. The catalyst may be volatile or non-volatile. The pyrolysis temperature and dwell time can vary as known in the art.

In some embodiments, the methods comprise preparation of a polymer gel by a sol gel process, condensation process or crosslinking process involving monomer precursor(s) and a crosslinking agent, two existing polymers and a crosslinking agent or a single polymer and a crosslinking agent, followed by pyrolysis of the polymer gel. The polymer gel may be dried (e.g., freeze dried) prior to pyrolysis; however drying is not necessarily required.

The target carbon properties can be derived from a variety of polymer chemistries provided the polymerization reaction produces a resin/polymer with the necessary carbon backbone. Different polymer families include novolacs, resoles, acrylates, styrenics, ureathanes, rubbers (neoprenes, styrene-butadienes, etc.), nylons, etc. The preparation of any of these polymer resins can occur via a number of different processes including sol gel, emulsion/suspension, solid state, solution state, melt state, etc. for either polymerization or crosslinking processes.

In some embodiments an electrochemical modifier is incorporated into the material as polymer. For example, the organic or carbon containing polymer, RF for example, is copolymerized with the polymer, which contains the electrochemical modifier. In one embodiment, the electrochemical modifier-containing polymer contains silicon. In one embodiment the polymer is tetraethylorthosiliane (TEOS). In one embodiment, a TEOS solution is added to the RF solution prior to or during polymerization. In another embodiment the polymer is a polysilane with organic side groups. In some cases, these side groups are methyl groups, in other cases these groups are phenyl groups, in other cases the side chains include phenyl, pyrol, acetate, vinyl, siloxane fragments. In some cases the side chain includes a group 14 element (silicon, germanium, tin or lead). In other cases, the side chain includes a group 13 element (boron, aluminum, boron, gallium, indium). In other cases the side chain includes a group 15 element (nitrogen, phosphorous, arsenic). In other cases, the side chain includes a group 16 element (oxygen, sulfur, selenium).

In another embodiment the electrochemical modifier includes a silole. In some cases, it is a phenol-silole or a silafluorene. In other cases, it is a poly-silole or a poly-silafluorene. In some cases, the silicon is replaced with germanium (germole or germafluorene), tin (stannole or stannaflourene) nitrogen (carbazole) or phosphorous (phosphole, phosphafluorene). In all cases the heteroatom containing material can be a small molecule, an oligomer or a polymer. Phosphorous atoms may or may not be also bonded to oxygen.

In some embodiments the reactant includes phosphorus. In certain other embodiments, the phosphorus is in the form of phosphoric acid. In certain other embodiments, the phosphorus can be in the form of a salt, wherein the anion of the salt includes one or more phosphate, phosphite, phosphide, hydrogen phosphate, dihydrogen phosphate, hexafluorophosphate, hypophosphite, polyphosphate, or pyrophosphate ions, or combinations thereof. In certain other embodiments, the phosphorus can be in the form of a salt, wherein the cation of the salt includes one or more phosphonium ions. The non-phosphate containing anion or cation pair for any of the above embodiments can be chosen for those known and described in the art. In the context, exemplary cations to pair with phosphate-containing anions include, but are not limited to, ammonium, tetraethylammonium, and tetramethylammonium ions. In the context, exemplary anions to pair with phosphate-containing cations include, but are not limited to, carbonate, dicarbonate, and acetate ions.

In some embodiments, the catalyst includes a basic volatile catalyst. For example, in one embodiment, the basic volatile catalyst includes ammonium carbonate, ammonium bicarbonate, ammonium acetate, ammonium hydroxide, or combinations thereof. In a further embodiment, the basic volatile catalyst is ammonium carbonate. In another further embodiment, the basic volatile catalyst is ammonium acetate.

In still other embodiments, the method includes admixing an acid. In certain embodiments, the acid is a solid at room temperature and pressure. In some embodiments, the acid is a liquid at room temperature and pressure. In some embodiments, the acid is a liquid at room temperature and pressure that does not provide dissolution of one or more of the other polymer precursors.

The acid may be selected from any number of acids suitable for the polymerization process. For example, in some embodiments the acid is acetic acid and in other embodiments the acid is oxalic acid. In further embodiments, the acid is mixed with the first or second solvent in a ratio of acid to solvent of 99:1, 90:10, 75:25, 50:50, 25:75, 20:80, 10:90 or 1:90. In other embodiments, the acid is acetic acid and the first or second solvent is water. In other embodiments, acidity is provided by adding a solid acid.

The total content of acid in the mixture can be varied to alter the properties of the final product. In some embodiments, the acid is present from about 1% to about 50% by weight of mixture. In other embodiments, the acid is present from about 5% to about 25%. In other embodiments, the acid is present from about 10% to about 20%, for example about 10%, about 15% or about 20%.

In certain embodiments, the polymer precursor components are blended together and subsequently held for a time and at a temperature sufficient to achieve polymerization. One or more of the polymer precursor components can have particle size less than about 20 mm in size, for example less than 10 mm, for example less than 7 mm, for example, less than 5 mm, for example less than 2 mm, for example less than 1 mm, for example less than 100 microns, for example less than 10 microns. In some embodiments, the particle size of one or more of the polymer precursor components is reduced during the blending process.

The blending of one or more polymer precursor components in the absence of solvent can be accomplished by methods described in the art, for example ball milling, jet milling, Fritsch milling, planetary mixing, and other mixing methodologies for mixing or blending solid particles while controlling the process conditions (e.g., temperature). The mixing or blending process can be accomplished before, during, and/or after (or combinations thereof) incubation at the reaction temperature.

Reaction parameters include aging the blended mixture at a temperature and for a time sufficient for the one or more polymer precursors to react with each other and form a polymer. In this respect, suitable aging temperature ranges from about room temperature to temperatures at or near the melting point of one or more of the polymer precursors. In some embodiments, suitable aging temperature ranges from about room temperature to temperatures at or near the glass transition temperature of one or more of the polymer precursors. For example, in some embodiments the solvent free mixture is aged at temperatures from about 20° C. to about 600° C., for example about 20° C. to about 500° C., for example about 20° C. to about 400° C., for example about 20° C. to about 300° C., for example about 20° C. to about 200° C. In certain embodiments, the solvent free mixture is aged at temperatures from about 50 to about 250° C.

The reaction duration is generally sufficient to allow the polymer precursors to react and form a polymer, for example the mixture may be aged anywhere from 1 hour to 48 hours, or more or less depending on the desired result. Typical embodiments include aging for a period of time ranging from about 2 hours to about 48 hours, for example in some embodiments aging includes about 12 hours and in other embodiments aging includes about 4-8 hours (e.g., about 6 hours).

In certain embodiments, an electrochemical modifier is incorporated during the above-described polymerization process. For example, in some embodiments, an electrochemical modifier in the form of metal particles, metal paste, metal salt, metal oxide or molten metal can be dissolved or suspended into the mixture from which the gel resin is produced.

Exemplary electrochemical modifiers for producing composite materials may fall into one or more than one of the chemical classifications. In some embodiments, the electrochemical modifier is a lithium salt, for example, but not limited to, lithium fluoride, lithium chloride, lithium carbonate, lithium hydroxide, lithium benzoate, lithium bromide, lithium formate, lithium hexafluorophosphate, lithium iodate, lithium iodide, lithium perchlorate, lithium phosphate, lithium sulfate, lithium tetraborate, lithium tetrafluoroborate, and combinations thereof.

In certain embodiments, the electrochemical modifier includes a metal, and exemplary species includes, but are not limited to aluminum isoproproxide, manganese acetate, nickel acetate, iron acetate, tin chloride, silicon chloride, and combinations thereof. In certain embodiments, the electrochemical modifier is a phosphate compound, including but not limited to phytic acid, phosphoric acid, ammonium dihydrogenphosphate, and combinations thereof. In certain embodiments, the electrochemical modifier includes silicon, and exemplary species includes, but are not limited to silicon powders, silicon nanotubes, polycrystalline silicon, nanocrystalline silicon, amorphous silicon, porous silicon, nano sized silicon, nano-featured silicon, nano-sized and nano-featured silicon, silicyne, and black silicon, and combinations thereof.

Electrochemical modifiers can be combined with a variety of polymer systems through either physical mixing or chemical reactions with latent (or secondary) polymer functionality. Examples of latent polymer functionality include, but are not limited to, epoxide groups, unsaturation (double and triple bonds), acid groups, alcohol groups, amine groups, basic groups. Crosslinking with latent functionality can occur via heteroatoms (e.g., vulcanization with sulfur, acid/base/ring opening reactions with phosphoric acid), reactions with organic acids or bases (described above), coordination to transition metals (including but not limited to Ti, Cr, Mn, Fe, Co, Ni, Cu, Zn, Zr, Nb, Mo, Ag, Au), ring opening or ring closing reactions (rotaxanes, spiro compounds, etc.).

Electrochemical modifiers can also be added to the polymer system through physical blending. Physical blending can include but is not limited to melt blending of polymers and/or co-polymers, the inclusion of discrete particles, chemical vapor deposition of the electrochemical modifier and coprecipitation of the electrochemical modifier and the main polymer material.

In some embodiments, the electrochemical modifier can be added via a metal salt solid, solution, or suspension. The metal salt solid, solution or suspension may comprise acids and/or alcohols to improve solubility of the metal salt. In yet another variation, the polymer gel (either before or after an optional drying step) is contacted with a paste comprising the electrochemical modifier. In yet another variation, the polymer gel (either before or after an optional drying step) is contacted with a metal or metal oxide sol comprising the desired electrochemical modifier.

In addition to the above exemplified electrochemical modifiers, the composite materials may comprise one or more additional forms (i.e., allotropes) of carbon. In this regard, it has been found that inclusion of different allotropes of carbon such as graphite, amorphous carbon, conductive carbon, carbon black, diamond, C60, carbon nanotubes (e.g., single and/or multi-walled), graphene and/or carbon fibers into the composite materials is effective to optimize the electrochemical properties of the composite materials. The various allotropes of carbon can be incorporated into the carbon materials during any stage of the preparation process described herein. For example, during the solution phase, during the gelation phase, during the curing phase, during the pyrolysis phase, during the milling phase, or after milling. In some embodiments, the second carbon form is incorporated into the composite material by adding the second carbon form before or during polymerization of the polymer gel as described in more detail herein. The polymerized polymer gel containing the second carbon form is then processed according to the general techniques described herein to obtain a carbon material containing a second allotrope of carbon.

In various embodiments, the carbon is produced from precursors with little or no solvent required for processing (solvent free). The structure of the polymer precursors suitable for use in a low solvent or essentially solvent free reaction mixture is not particularly limited, provided that the polymer precursor is capable of reacting with another polymer precursor or with a second polymer precursor to form a polymer. Polymer precursors include, but are not limited to, amine-containing compounds, alcohol-containing compounds and carbonyl-containing compounds, for example in some embodiments suitable polymer precursors include, but are not limited to, an alcohol, a phenol, a polyalcohol, a sugar, an alkyl amine, an aromatic amine, an aldehyde, a ketone, a carboxylic acid, an ester, a urea, an acid halide and an isocyanate.

In one embodiment employing a low or essentially solvent free reaction mixture, the method includes use of a first and second polymer precursor, and in some embodiments the first or second polymer precursor is a carbonyl containing compound and the other of the first or second polymer precursor is an alcohol containing compound. In some embodiments, a first polymer precursor is a phenolic compound and a second polymer precursor is an aldehyde compound (e.g., formaldehyde). In one embodiment, of the method the phenolic compound is phenol, resorcinol, catechol, hydroquinone, phloroglucinol, or a combination thereof; and the aldehyde compound is formaldehyde, acetaldehyde, propionaldehyde, butyraldehyde, benzaldehyde, cinnamaldehyde, or a combination thereof. In a further embodiment, the phenolic compound is resorcinol, phenol or a combination thereof, and the aldehyde compound is formaldehyde. In yet further embodiments, the phenolic compound is resorcinol and the aldehyde compound is formaldehyde. In some embodiments, the polymer precursors are alcohols and carbonyl compounds (e.g., resorcinol and aldehyde) and they are present in a ratio of about 0.5:1.0, respectively.

The polymer precursor materials suitable for low or essentially solvent free reaction mixture as disclosed herein include (a) alcohols, phenolic compounds, and other mono- or polyhydroxy compounds and (b) aldehydes, ketones, and combinations thereof. Representative alcohols in this context include straight chain and branched, saturated and unsaturated alcohols. Suitable phenolic compounds include polyhydroxy benzene, such as a dihydroxy or trihydroxy benzene. Representative polyhydroxy benzenes include resorcinol (i.e., 1,3-dihydroxy benzene), catechol, hydroquinone, and phloroglucinol. Other suitable compounds in this regard are bisphenols, for instance, bisphenol A. Mixtures of two or more polyhydroxy benzenes can also be used. Phenol (monohydroxy benzene) can also be used. Representative polyhydroxy compounds include sugars, such as glucose, sucrose, fructose, chitin and other polyols, such as mannitol. Aldehydes in this context include: straight chain saturated aldeydes such as methanal (formaldehyde), ethanal (acetaldehyde), propanal (propionaldehyde), butanal (butyraldehyde), and the like; straight chain unsaturated aldehydes such as ethenone and other ketenes, 2-propenal (acrylaldehyde), 2-butenal (crotonaldehyde), 3 butenal, and the like; branched saturated and unsaturated aldehydes; and aromatic-type aldehydes such as benzaldehyde, salicylaldehyde, hydrocinnamaldehyde, and the like. Suitable ketones include straight chain saturated ketones such as propanone and 2 butanone, and the like; straight chain unsaturated ketones such as propenone, 2 butenone, and 3 butenone (methyl vinyl ketone) and the like; branched saturated and unsaturated ketones; and aromatic-type ketones such as methyl benzyl ketone (phenylacetone), ethyl benzyl ketone, and the like. The polymer precursor materials can also be combinations of the precursors described above.

In some embodiments, one polymer precursor in the low or essentially solvent free reaction mixture is an alcohol-containing species and another polymer precursor is a carbonyl-containing species. The relative amounts of alcohol-containing species (e.g., alcohols, phenolic compounds and mono- or poly-hydroxy compounds or combinations thereof) reacted with the carbonyl containing species (e.g., aldehydes, ketones or combinations thereof) can vary substantially. In some embodiments, the ratio of alcohol-containing species to aldehyde species is selected so that the total moles of reactive alcohol groups in the alcohol-containing species is approximately the same as the total moles of reactive carbonyl groups in the aldehyde species. Similarly, the ratio of alcohol-containing species to ketone species may be selected so that the total moles of reactive alcohol groups in the alcohol containing species is approximately the same as the total moles of reactive carbonyl groups in the ketone species. The same general 1:1 molar ratio holds true when the carbonyl-containing species includes a combination of an aldehyde species and a ketone species.

In other embodiments, the polymer precursor in the low or essentially solvent free reaction mixture is a urea or an amine containing compound. For example, in some embodiments the polymer precursor is urea, melamine, hexamethylenetetramine (HMT) or combination thereof. Other embodiments include polymer precursors selected from isocyanates or other activated carbonyl compounds such as acid halides and the like.

Some embodiments of the disclosed methods include preparation of low or solvent-free polymer gels (and carbon materials) comprising electrochemical modifiers. Such electrochemical modifiers include, but are not limited to nitrogen, silicon, and sulfur. In other embodiments, the electrochemical modifier includes fluorine, iron, tin, silicon, nickel, aluminum, zinc, or manganese. The electrochemical modifier can be included in the preparation procedure at any step. For example, in some the electrochemical modifier is admixed with the mixture, the polymer phase or the continuous phase.

The blending of one or more polymer precursor components in the absence of solvent can be accomplished by methods described in the art, for example ball milling, jet milling, Fritsch milling, planetary mixing, and other mixing methodologies for mixing or blending solid particles while controlling the process conditions (e.g., temperature). The mixing or blending process can be accomplished before, during, and/or after (or combinations thereof) incubation at the reaction temperature.

Reaction parameters include aging the blended mixture at a temperature and for a time sufficient for the one or more polymer precursors to react with each other and form a polymer. In this respect, suitable aging temperature ranges from about room temperature to temperatures at or near the melting point of one or more of the polymer precursors. In some embodiments, suitable aging temperature ranges from about room temperature to temperatures at or near the glass transition temperature of one or more of the polymer precursors. For example, in some embodiments the solvent free mixture is aged at temperatures from about 20° C. to about 600° C., for example about 20° C. to about 500° C., for example about 20° C. to about 400° C., for example about 20° C. to about 300° C., for example about 20° C. to about 200° C. In certain embodiments, the solvent free mixture is aged at temperatures from about 50 to about 250° C.

The porous carbon material can be achieved via pyrolysis of a polymer produced from precursors materials as described above. In some embodiments, the porous carbon material includes an amorphous activated carbon that is produced by pyrolysis, physical or chemical activation, or combination thereof in either a single process step or sequential process steps.

The temperature and dwell time of pyrolysis can be varied, for example the dwell time van vary from 1 min to 10 min, from 10 min to 30 min, from 30 min to 1 hour, for 1 hour to 2 hours, from 2 hours to 4 hours, from 4 hours to 24 h. The temperature can be varied, for example, the pyrolysis temperature can vary from 200 to 300 C, from 250 to 350 C, from 350 C to 450 C, from 450 C to 550 C, from 540 C to 650 C, from 650 C to 750 C, from 750 C to 850 C, from 850 C to 950 C, from 950 C to 1050 C, from 1050 C to 1150 C, from 1150 C to 1250 C. The pyrolysis can be accomplished in an inert gas, for example nitrogen, or argon.

In some embodiments, an alternate gas is used to further accomplish carbon activation. In certain embodiments, pyrolysis and activation are combined. Suitable gases for accomplishing carbon activation include, but are not limited to, carbon dioxide, carbon monoxide, water (steam), air, oxygen, and further combinations thereof. The temperature and dwell time of activation can be varied, for example the dwell time van vary from 1 min to 10 min, from 10 min to 30 min, from 30 min to 1 hour, for 1 hour to 2 hours, from 2 hours to 4 hours, from 4 hours to 24 h. The temperature can be varied, for example, the pyrolysis temperature can vary from 200 to 300 C, from 250 to 350 C, from 350 C to 450 C, from 450 C to 550 C, from 540 C to 650 C, from 650 C to 750 C, from 750 C to 850 C, from 850 C to 950 C, from 950 C to 1050 C, from 1050 C to 1150 C, from 1150 C to 1250 C.

Either prior to the pyrolysis, and/or after pyrolysis, and/or after activation, the carbon may be subjected to a particle size reduction. The particle size reduction can be accomplished by a variety of techniques known in the art, for example by jet milling in the presence of various gases including air, nitrogen, argon, helium, supercritical steam, and other gases known in the art. Other particle size reduction methods, such as grinding, ball milling, jet milling, water jet milling, and other approaches known in the art are also envisioned.

The porous carbon scaffold may be in the form of particles. The particle size and particle size distribution can be measured by a variety of techniques known in the art and can be described based on fractional volume. In this regard, the Dv50 of the carbon scaffold may be between 10 nm and 10 mm, for example between 100 nm and 1 mm, for example between 1 μm and 100 μm, for example between 2 μm and 50 μm, example between 3 μm and 30 μm, example between 4 μm and 20 μm, example between 5 μm and 10 μm. In certain embodiments, the Dv50 is less than 1 mm, for example less than 100 μm, for example less than 50 μm, for example less than 30 μm, for example less than 20 μm, for example less than 10 μm, for example less than 8 μm, for example less than 5 μm, for example less than 3 μm, for example less than 1 μm. In certain embodiments, the Dv100 is less than 1 mm, for example less than 100 μm, for example less than 50 μm, for example less than 30 μm, for example less than 20 μm, for example less than 10 μm, for example less than 8 μm, for example less than 5 μm, for example less than 3 μm, for example less than 1 μm. In certain embodiments, the Dv99 is less than 1 mm, for example less than 100 μm, for example less than 50 μm, for example less than 30 μm, for example less than 20 μm, for example less than 10 μm, for example less than 8 μm, for example less than 5 μm, for example less than 3 μm, for example less than 1 μm. In certain embodiments, the Dv90 is less than 1 mm, for example less than 100 μm, for example less than 50 μm, for example less than 30 μm, for example less than 20 μm, for example less than 10 μm, for example less than 8 μm, for example less than 5 μm, for example less than 3 μm, for example less than 1 μm. In certain embodiments, the Dv0 is greater than 10 nm, for example greater than 100 nm, for example greater than 500 nm, for example greater than 1 μm, for example greater than 2 μm, for example greater than 5 μm, for example greater than 10 μm. In certain embodiments, the Dv1 is greater than 10 nm, for example greater than 100 nm, for example greater than 500 nm, for example greater than 1 μm, for example greater than 2 μm, for example greater than 5 μm, for example greater than 10 μm. In certain embodiments, the Dv10 is greater than 10 nm, for example greater than 100 nm, for example greater than 500 nm, for example greater than 1 μm, for example greater than 2 μm, for example greater than 5 μm, for example greater than 10 μm.

In some embodiments, the surface area of the porous carbon scaffold can comprise a surface area greater than 400 m²/g, for example greater than 500 m²/g, for example greater than 750 m²/g, for example greater than 1000 m²/g, for example greater than 1250 m²/g, for example greater than 1500 m²/g, for example greater than 1750 m²/g, for example greater than 2000 m²/g, for example greater than 2500 m²/g, for example greater than 3000 m²/g. In other embodiments, the surface area of the porous carbon scaffold can be less than 500 m²/g. In some embodiments, the surface area of the porous carbon scaffold is between 200 and 500 m²/g. In some embodiments, the surface area of the porous carbon scaffold is between 100 and 200 m²/g. In some embodiments, the surface area of the porous carbon scaffold is between 50 and 100 m²/g. In some embodiments, the surface area of the porous carbon scaffold is between 10 and 50 m²/g. In some embodiments, the surface area of the porous carbon scaffold can be less than 10 m²/g.

Surface area, pore volume, and % micro/meso/macro pore size fractions are determined via nitrogen gas adsorption on a Micromeritics Tristar II+porosimeter at 77K using the density functional theory (DFT) model with carbon slit pore assumption from a relative partial pressure range of 0.01-0.99. In particular, the specific surface area (m²/g) is calculated using the Brunauer-Emmett-Teller (BET) method from the relative partial pressure range of 0.01-0.1. The pore volume is determined from the single point adsorption of gas at a partial pressure of 0.97. The % micro/meso/macro pore size fractions is determined from the tabular plot of pore widths versus cumulative pore volume (cm³/g) wherein the % microporosity is the fraction of cumulative pore volume contributed from the 0-2 nm pore width, the % mesopore fraction is the cumulative pore volume between 2-50 nm pore widths, and % macropore fraction is the cumulative pore volume greater than 50 nm.

One of ordinary skill in the art understands that nitrogen adsorption porosimetry is a universally accepted method for measuring surface area, pore volume, and pore width for a multitude of materials. % micro-, % meso-, and % macro-pore sizes are determined via the cumulative pore volume determined by the nitrogen adsorption isotherm. Pore size ranges of micro (>0-2 nm), meso (2-50 nm), and macro (>50 nm) are those defined by the Internation Union of Pure and Applied Chemistry (IUPAC) which recommends the use of nitrogen/gas phase adsorption as a viable method for measuring these properties.

In some embodiments, the pore volume of the porous carbon scaffold is greater than 0.4 cm³/g, for example greater than 0.5 cm³/g, for example greater than 0.6 cm³/g, for example greater than 0.7 cm³/g, for example greater than 0.8 cm³/g, for example greater than 0.9 cm³/g, for example greater than 1.0 cm³/g, for example greater than 1.1 cm³/g, for example greater than 1.2 cm³/g, for example greater than 1.4 cm³/g, for example greater than 1.6 cm³/g, for example greater than 1.8 cm³/g, for example greater than 2.0 cm³/g. In other embodiments, the pore volume of the porous silicon scaffold is less than 0.5 cm³/g, for example between 0.1 cm³/g and 0.5 cm³/g. In certain other embodiments, the pore volume of the porous silicon scaffold is between 0.01 cm³/g and 0.1 cm³/g.

In some other embodiments, the porous carbon scaffold is an amorphous activated carbon with a pore volume between 0.2 and 2.0 cm³/g. In certain embodiments, the carbon is an amorphous activated carbon with a pore volume between 0.4 and 1.5 cm³/g. In certain embodiments, the carbon is an amorphous activated carbon with a pore volume between 0.5 and 1.2 cm³/g. In certain embodiments, the carbon is an amorphous activated carbon with a pore volume between 0.6 and 1.0 cm³/g.

In some other embodiments, the porous carbon scaffold includes a tap density of less than 1.0 g/cm³, for example less than 0.8 g/cm³, for example less than 0.6 g/cm³, for example less than 0.5 g/cm³, for example less than 0.4 g/cm³, for example less than 0.3 g/cm³, for example less than 0.2 g/cm³, for example less than 0.1 g/cm³.

The surface functionality of the porous carbon scaffold can vary. One property which can be predictive of surface functionality is the pH of the porous carbon scaffold. The presently disclosed porous carbon scaffolds comprise pH values ranging from less than 1 to about 14, for example less than 5, from 5 to 8 or greater than 8. In some embodiments, the pH of the porous carbon is less than 4, less than 3, less than 2 or even less than 1. In other embodiments, the pH of the porous carbon is between about 5 and 6, between about 6 and 7, between about 7 and 8 or between 8 and 9 or between 9 and 10. In still other embodiments, the pH is high and the pH of the porous carbon ranges is greater than 8, greater than 9, greater than 10, greater than 11, greater than 12, or even greater than 13.

The pore volume distribution of the porous carbon scaffold can vary. For example, the % micropores can comprise less than 30%, for example less than 20%, for example less than 10%, for example less than 5%, for example less than 4%, for example less than 3%, for example less than 2%, for example less than 1%, for example less than 0.5%, for example less than 0.2%, for example, less than 0.1%. In certain embodiments, there is no detectable micropore volume in the porous carbon scaffold.

The mesopores comprising the porous carbon scaffold can vary. For example, the % mesopores can comprise less than 30%, for example less than 20%, for example less than 10%, for example less than 5%, for example less than 4%, for example less than 3%, for example less than 2%, for example less than 1%, for example less than 0.5%, for example less than 0.2%, for example, less than 0.1%. In certain embodiments, there is no detectable mesopore volume in the porous carbon scaffold.

In some embodiments, the pore volume distribution of the porous carbon scaffold includes more than 50% macropores, for example more than 60% macropores, for example more than 70% macropores, for example more than 80% macropores, for example more than 90% macropores, for example more than 95% macropores, for example more than 98% macropores, for example more than 99% macropores, for example more than 99.5% macropores, for example more than 99.9% macropores.

In various embodiments, the pore volume of the porous carbon scaffold includes a blend of micropores (less than 2 nm), mesopores (2-50 nm), and macropores (greater than 50 nm). Accordingly, in certain embodiments, the porous carbon scaffold includes 0-20% micropores, 30-70% mesopores, and less than 10% macropores. In certain other embodiments, the porous carbon scaffold includes 0-20% micropores, 0-20% mesopores, and 70-95% macropores. In certain other embodiments, the porous carbon scaffold includes 20-50% micropores, 50-80% mesopores, and 0-10% macropores. In certain other embodiments, the porous carbon scaffold includes 40-60% micropores, 40-60% mesopores, and 0-10% macropores. In certain other embodiments, the porous carbon scaffold includes 80-95% micropores, 0-10% mesopores, and 0-10% macropores. In certain other embodiments, the porous carbon scaffold includes 0-10% micropores, 30-50% mesopores, and 50-70% macropores. In certain other embodiments, the porous carbon scaffold includes 0-10% micropores, 70-80% mesopores, and 0-20% macropores. In certain other embodiments, the porous carbon scaffold includes 0-20% micropores, 70-95% mesopores, and 0-10% macropores. In certain other embodiments, the porous carbon scaffold includes 0-10% micropores, 70-95% mesopores, and 0-20% macropores.

In certain embodiments, the % of pore volume in the porous carbon scaffold representing pores between 100 and 1000 A (10 and 100 nm) includes greater than 30% of the total pore volume, for example greater than 40% of the total pore volume, for example greater than 50% of the total pore volume, for example greater than 60% of the total pore volume, for example greater than 70% of the total pore volume, for example greater than 80% of the total pore volume, for example greater than 90% of the total pore volume, for example greater than 95% of the total pore volume, for example greater than 98% of the total pore volume, for example greater than 99% of the total pore volume, for example greater than 99.5% of the total pore volume, for example greater than 99.9% of the total pore volume.

In certain embodiments, the pycnometry density of the porous carbon scaffold ranges from about 1 g/cc to about 3 g/cc, for example from about 1.5 g/cc to about 2.3 g/cc. In other embodiments, the skeletal density ranges from about 1.5 cc/g to about 1.6 cc/g, from about 1.6 cc/g to about 1.7 cc/g, from about 1.7 cc/g to about 1.8 cc/g, from about 1.8 cc/g to about 1.9 cc/g, from about 1.9 cc/g to about 2.0 cc/g, from about 2.0 cc/g to about 2.1 cc/g, from about 2.1 cc/g to about 2.2 cc/g or from about 2.2 cc/g to about 2.3 cc/g, from about 2.3 cc to about 2.4 cc/g, for example from about 2.4 cc/g to about 2.5 cc/g.

### 3. Agglomerants of Porous Carbon Materials

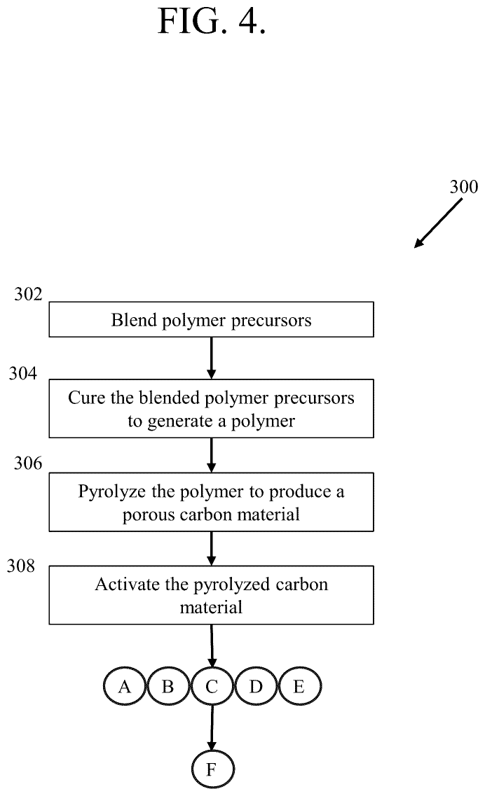

Referring to FIG. 4, a process 300 describes creation of an agglomerated activated carbon material that is later used to create a silicon-carbon composite material. At a block 302, polymer precursors (as described above) are blended. At a block 304, the blended polymer precursors are cured to generate a polymer. At a block 306, the polymer is pyrolyzed to produce a porous carbon material. After the block 306, one of various agglomerated carbon material creation processes are performed followed by CVI and optional CVD/chemical vapor passivation (CVP).

Non-exclusive examples of agglomerants (e.g., binders) that may be used to agglomerate activated carbon material include fluoro polymers, such as, for example, PTFE (polytetrafluoroethylene, i.e., Teflon®), PFA (perfluoroalkoxy polymer resin), FEP (fluorinated ethylene propylene), ETFE (polyethylenetetrafluoroethylene, i.e., Tefzel™ and Fluon®), PVF (polyvinyl fluoride, i.e., Tedlar®), ECTFE (polyethylenechlorotrifluoroethylene, i.e., Halar®), PVDF (polyvinylidene fluoride, i.e., Kynar®), polyacrylic acid (PAA), PCTFE (polychlorotrifluoroethylene, i.e., Kel-F® and CTFE), trifluoroethanol, novolac polyethylene glycol (PEG), lico, CMC (carboxymethylcellulose), and combinations thereof.

The porous carbon scaffold may be in the form of agglomerated carbon particles. The agglomerated carbon particle size and particle size distribution can be measured by a variety of techniques known in the art and can be described based on fractional volume. In various embodiments, particle (agglomerate) size distribution range could be 100 μm to 500 μm, 100 μm to 1 mm, 500 μm to 1 mm, 1 mm to 5 cm, or 1 mm to 10 mm. In this regard, the Dv50 of the agglomerated carbon particles may be between 100 μm and 500 μm, for example between 100 μm and 1 mm, for example between 1 mm and 1 cm, for example between 1 cm and 2 cm. In certain embodiments, the Dv100 is less than 2 cm, for example less than 1 cm, for example less than 100 μm. In certain embodiments, the Dv99 is less than 2 cm, for example less than 1 cm, for example less than 100 μm. In certain embodiments, the Dv90 is less than 2 cm, for example less than 1 cm, for example less than 10 μm, for example greater than 100 μm, for example greater than 5 mm, for example greater than 2 mm. In certain embodiments, the Dv1 is greater than 10 μm, for example greater than 100 μm, for example greater than 1 mm, for example greater than 2 mm. In certain embodiments, the Dv10 is greater than 10 μm, for example greater than 100 μm, for example greater than 1 mm, for example greater than 2 mm.

In some embodiments, the surface area of the agglomerated carbon particles can comprise a surface area greater than 400 m²/g, for example greater than 500 m²/g, for example greater than 750 m²/g, for example greater than 1000 m²/g, for example greater than 1250 m²/g, for example greater than 1500 m²/g, for example greater than 1750 m²/g, for example greater than 2000 m²/g, for example greater than 2500 m²/g, for example greater than 3000 m²/g. In other embodiments, the surface area of the agglomerated carbon particles can be less than 500 m²/g. In some embodiments, the surface area of the agglomerated carbon particles is between 200 and 500 m²/g. In some embodiments, the surface area of the agglomerated carbon particles is between 100 and 200 m²/g. In some embodiments, the surface area of the agglomerated carbon particles is between 50 and 100 m²/g. In some embodiments, the surface area of the agglomerated carbon particles is between 10 and 50 m²/g. In some embodiments, the surface area of the agglomerated carbon particles can be less than 10 m²/g.

Surface area, pore volume, and % micro/meso/macro pore size fractions are determined via nitrogen gas adsorption on a Micromeritics Tristar II+porosimeter at 77K using the density functional theory (DFT) model with carbon slit pore assumption from a relative partial pressure range of 0.01-0.99. In particular, the specific surface area (m²/g) is calculated using the BET method from the relative partial pressure range of 0.01-0.1. The pore volume is determined from the single point adsorption of gas at a partial pressure of 0.97. The % micro/meso/macro pore size fractions is determined from the tabular plot of pore widths versus cumulative pore volume (cm³/g) wherein the % microporosity is the fraction of cumulative pore volume contributed from the 0-2 nm pore width, the % mesopore fraction is the cumulative pore volume between 2-50 nm pore widths, and % macropore fraction is the cumulative pore volume greater than 50 nm.

In some embodiments, the pore volume of the agglomerated carbon particles is greater than 0.4 cm³/g, for example greater than 0.5 cm³/g, for example greater than 0.6 cm³/g, for example greater than 0.7 cm³/g, for example greater than 0.8 cm³/g, for example greater than 0.9 cm³/g, for example greater than 1.0 cm³/g, for example greater than 1.1 cm³/g, for example greater than 1.2 cm³/g, for example greater than 1.4 cm³/g, for example greater than 1.6 cm³/g, for example greater than 1.8 cm³/g, for example greater than 2.0 cm³/g. In other embodiments, the pore volume of the agglomerated carbon particles is less than 0.5 cm³/g, for example between 0.1 cm³/g and 0.5 cm³/g. In certain other embodiments, the pore volume of the agglomerated carbon particles is between 0.01 cm³/g and 0.1 cm³/g.

In some other embodiments, the agglomerated carbon particles are an amorphous activated carbon with a pore volume between 0.2 and 2.0 cm³/g. In certain embodiments, the agglomerated carbon particles are an amorphous activated carbon with a pore volume between 0.4 and 1.5 cm³/g. In certain embodiments, the agglomerated carbon particles are an amorphous activated carbon with a pore volume between 0.5 and 1.2 cm³/g. In certain embodiments, the agglomerated carbon particles are an amorphous activated carbon with a pore volume between 0.6 and 1.0 cm³/g.

In some other embodiments, the agglomerated carbon particles include a tap density of less than 1.0 g/cm³, for example less than 0.8 g/cm³, for example less than 0.6 g/cm³, for example less than 0.5 g/cm³, for example less than 0.4 g/cm³, for example less than 0.3 g/cm³, for example less than 0.2 g/cm³, for example less than 0.1 g/cm³.

The surface functionality of the agglomerated carbon particles can vary. One property which can be predictive of surface functionality is the pH of the agglomerated carbon particles. The presently disclosed agglomerated carbon particles comprise pH values ranging from less than 1 to about 14, for example less than 5, from 5 to 8 or greater than 8. In some embodiments, the pH of the agglomerated carbon particles is less than 4, less than 3, less than 2 or even less than 1. In other embodiments, the pH of the agglomerated carbon particles is between about 5 and 6, between about 6 and 7, between about 7 and 8 or between 8 and 9 or between 9 and 10. In still other embodiments, the pH is high and the pH of the agglomerated carbon particles ranges is greater than 8, greater than 9, greater than 10, greater than 11, greater than 12, or even greater than 13.

The pore volume distribution of the agglomerated carbon particles can vary. For example, the % micropores can include less than 30%, for example less than 20%, for example less than 10%, for example less than 5%, for example less than 4%, for example less than 3%, for example less than 2%, for example less than 1%, for example less than 0.5%, for example less than 0.2%, for example, less than 0.1%. In certain embodiments, there is no detectable micropore volume in the agglomerated carbon particles.

The mesopores comprising the agglomerated carbon particles can vary. For example, the % mesopores can include less than 30%, for example less than 20%, for example less than 10%, for example less than 5%, for example less than 4%, for example less than 3%, for example less than 2%, for example less than 1%, for example less than 0.5%, for example less than 0.2%, for example, less than 0.1%. In certain embodiments, there is no detectable mesopore volume in the agglomerated carbon particles.

In some embodiments, the pore volume distribution of the agglomerated carbon particles includes more than 50% macropores, for example more than 60% macropores, for example more than 70% macropores, for example more than 80% macropores, for example more than 90% macropores, for example more than 95% macropores, for example more than 98% macropores, for example more than 99% macropores, for example more than 99.5% macropores, for example more than 99.9% macropores.

In various embodiments, the pore volume of the agglomerated carbon particles includes a blend of micropores (less than 2 nm), mesopores (2-50 nm), and macropores (greater than 50 nm). Accordingly, in certain embodiments, the agglomerated carbon particles include 0-20% micropores, 30-70% mesopores, and less than 10% macropores. In certain other embodiments, the agglomerated carbon particles include 0-20% micropores, 0-20% mesopores, and 70-95% macropores. In certain other embodiments, the agglomerated carbon particles include 20-50% micropores, 50-80% mesopores, and 0-10% macropores. In certain other embodiments, the agglomerated carbon particles include 40-60% micropores, 40-60% mesopores, and 0-10% macropores. In certain other embodiments, the agglomerated carbon particles include 80-95% micropores, 0-10% mesopores, and 0-10% macropores. In certain other embodiments, the agglomerated carbon particles include 0-10% micropores, 30-50% mesopores, and 50-70% macropores. In certain other embodiments, the agglomerated carbon particles include 0-10% micropores, 70-80% mesopores, and 0-20% macropores. In certain other embodiments, the agglomerated carbon particles include 0-20% micropores, 70-95% mesopores, and 0-10% macropores. In certain other embodiments, the agglomerated carbon particles include 0-10% micropores, 70-95% mesopores, and 0-20% macropores.

In certain embodiments, the % of pore volume in the agglomerated carbon particles representing pores between 100 and 1000 A (10 and 100 nm) include greater than 30% of the total pore volume, for example greater than 40% of the total pore volume, for example greater than 50% of the total pore volume, for example greater than 60% of the total pore volume, for example greater than 70% of the total pore volume, for example greater than 80% of the total pore volume, for example greater than 90% of the total pore volume, for example greater than 95% of the total pore volume, for example greater than 98% of the total pore volume, for example greater than 99% of the total pore volume, for example greater than 99.5% of the total pore volume, for example greater than 99.9% of the total pore volume.

In certain embodiments, the pycnometry density of the agglomerated carbon particles ranges from about 1 g/cc to about 3 g/cc, for example from about 1.5 g/cc to about 2.3 g/cc. In other embodiments, the skeletal density ranges from about 1.5 cc/g to about 1.6 cc/g, from about 1.6 cc/g to about 1.7 cc/g, from about 1.7 cc/g to about 1.8 cc/g, from about 1.8 cc/g to about 1.9 cc/g, from about 1.9 cc/g to about 2.0 cc/g, from about 2.0 cc/g to about 2.1 cc/g, from about 2.1 cc/g to about 2.2 cc/g or from about 2.2 cc/g to about 2.3 cc/g, from about 2.3 cc to about 2.4 cc/g, for example from about 2.4 cc/g to about 2.5 cc/g.

### A. Fluidized Carbon Scaffold and Undissolved Agglomerant (i.e., Immiscible in Liquid)

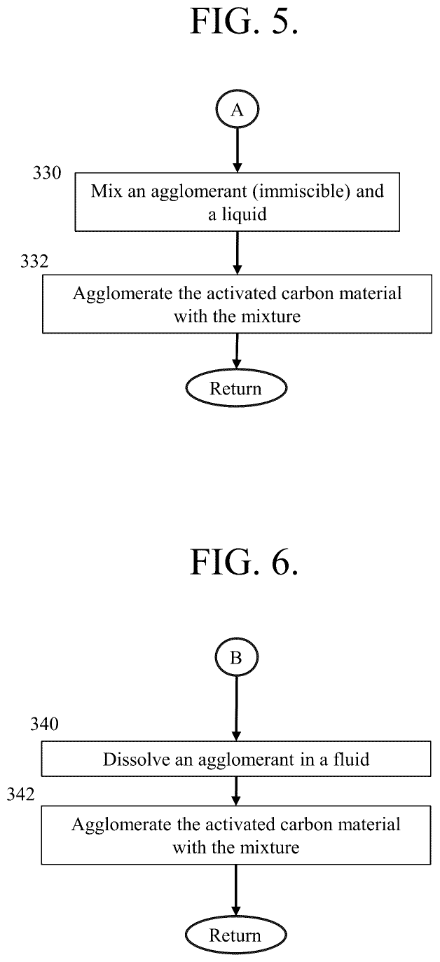

Referring to FIG. 5, at a block 330, an agglomerant (e.g., an immiscible binder, such as CMC) is mixed with a liquid, e.g., water, isopropyl alcohol (IPA). At a block 332, the agglomerant and liquid mixture is combined with the activated carbon material to produce an agglomerated carbon material.

### B. Fluidized Carbon Scaffold and Dissolved Agglomerant

Referring to FIG. 6, at a block 340, an agglomerant is dissolved in a fluid. At a block 342, the dissolved agglomerant is combined with the activated carbon material to produce an agglomerated carbon material. Examples of the fluid include water, isopropyl alcohol (IPA), acetone, methanol, benzene and low molecular weight PAA.

C. Carbon Binded by Friction without Agglomerant

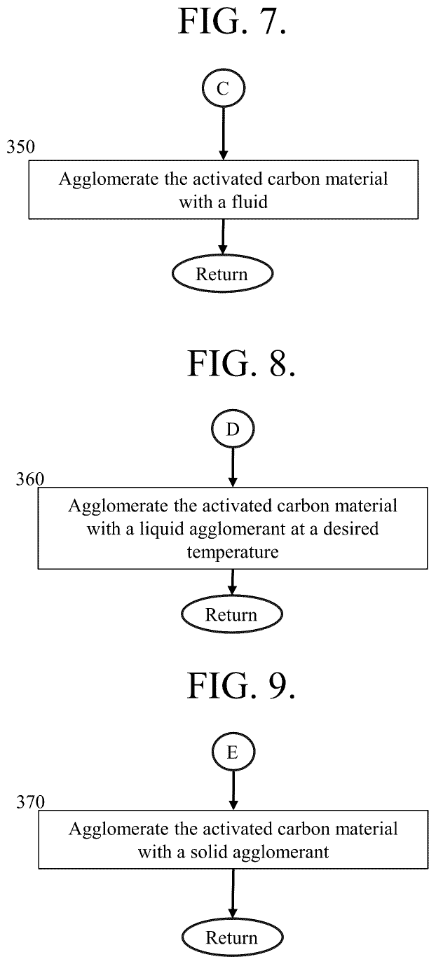

Referring to FIG. 7, at a block 350, a fluid is combined with the activated carbon material to produce an agglomerated carbon material due to friction. Examples of the fluid include water and isopropyl alcohol.

### D. Agglomerant in Liquid State for Possible Extrusion of Carbon Scaffold

Referring to FIG. 8, at a block 360, a liquid agglomerant is combined with the activated carbon material to produce an agglomerated carbon material. This combination may be performed at an elevated temperature for accelerating the combination. An example of the liquid agglomerant includes low molecular weight PEG.

The resulting agglomerated carbon material may be in a malleable form, thus allowing for extrusion. An extrusion of the agglomerated carbon material may be inserted directly into a reactor/kiln, such as fluidized bed reactor, convection-thermal assisted (CTA) reactor, vibratory bed reactor, roller hearth furnace, rotary kiln, belt furnace, etc.

E. Carbon Scaffold Mixed with Dry Agglomerant

Referring to FIG. 9, at a block 370, a solid/dry agglomerant is combined with the activated carbon material to produce an agglomerated carbon material. An example of the liquid agglomerant includes PTFE.

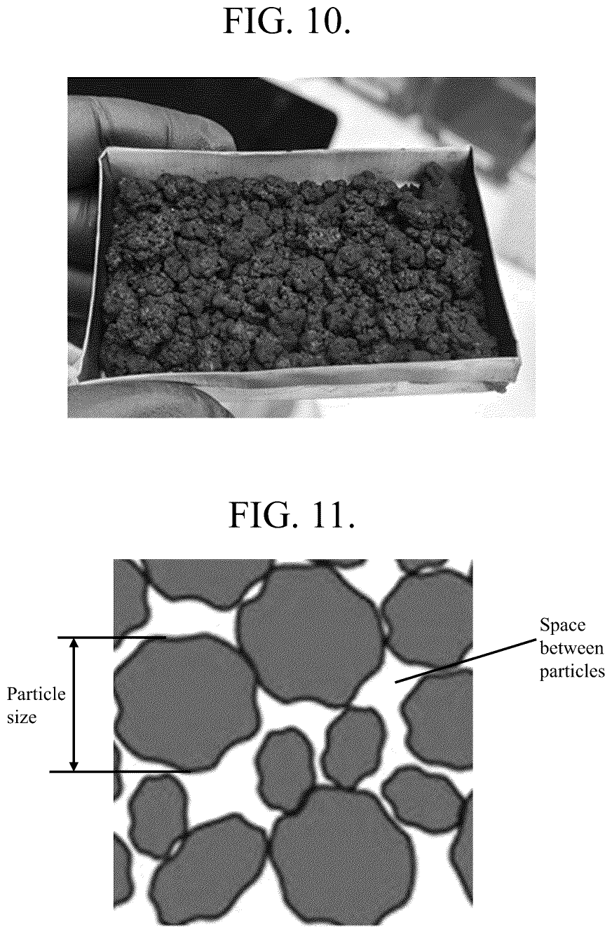

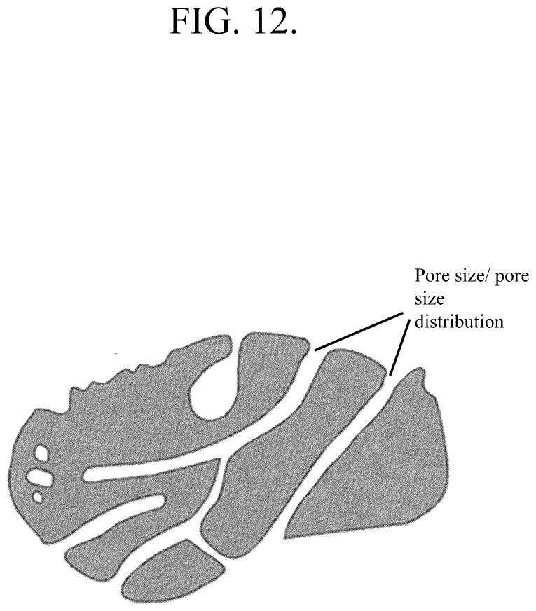

Referring to FIGS. 10-12, an agglomeration of porous carbon particles are shown. The agglomerated porous carbon particles include agglomeration voids (i.e., spaces between individual particles) having various size ranges, silicon-carbon particles having various size ranges, and pores with the silicon-carbon particles having various size ranges/pore volume distribution ranges.

### 4. Silicon Production Via Chemical Vapor Infiltration (CVI)

CVD is a process wherein a substrate provides a solid surface comprising the first component of the composite, and the gas thermally decomposes on this solid surface to provide the second component of composite. Such a CVD approach can be employed, for instance, to create Si—C composite materials wherein the silicon is coating on the outside surface of silicon particles. Alternatively, CVI is a process wherein a substrate provides a porous scaffold comprising the first component of the composite, and the gas thermally decomposes on into the porosity (into the pores) of the porous scaffold material to provide the second component of composite.

In an embodiment, silicon is created within the pores of the porous carbon scaffold by subjecting the porous carbon particles to a silicon containing precursor gas at elevated temperature and the presence of a silicon-containing gas, preferably silane, in order to decompose said gas into silicon. In some embodiments, the silicon containing gas includes, but are not limited to, a higher-order silane (such as di-, tri-, and/or tetrasilane), chlorosilane(s) (such as mono-, di-, tri-, and tetrachlorosilane) or mixtures thereof.

The silicon containing precursor gas can be mixed with other inert gas(es), for example, nitrogen gas, or hydrogen gas, or argon gas, or helium gas, or combinations thereof. The temperature and time of processing can be varied, for example the temperature can be between 200 and 900 C, for example between 200 and 250 C, for example between 250 and 300 C, for example between 300 and 350 C, for example between 300 and 400 C, for example 300 and 500 C, for example between 350 and 450 C, for example between 350 and 400 C, for example 350 and 500 C, for example 350 to 550 C, for example between 400 and 500 C, for example between 500 and 600 C, for example between 600 and 700 C, for example between 700 and 800 C, for example between 800 and 900 C, for example between 600 and 1100 C.

The mixture of gas can comprise between 0.1 and 1% silane and remainder inert gas. Alternatively, the mixture of gas can comprise between 1% and 10% silane and remainder inert gas. Alternatively, the mixture of gas can comprise between 10% and 20% silane and remainder inert gas. Alternatively, the mixture of gas can comprise between 20% and 50% silane and remainder inert gas. Alternatively, the mixture of gas can comprise above 50% silane and remainder inert gas. Alternatively, the gas can essentially be 100% silane gas. Suitable inert gases include, but are not limited to, hydrogen, nitrogen, argon, and combinations thereof.

The pressure for the CVI process can be varied. In some embodiments, the pressure is atmospheric pressure. In some embodiments, the pressure is below atmospheric pressure. In some embodiments, the pressure is above atmospheric pressure.

### 5. Silicon Production Via CVI Employing Agglomerated Porous Carbon Particles

In some embodiments, after the porous carbon is formed into an agglomerated form having desired property ranges as described above, an electrochemical modifier is grown/infiltrated into the pores of the agglomerated porous carbon by the CVI process, such as that described above.

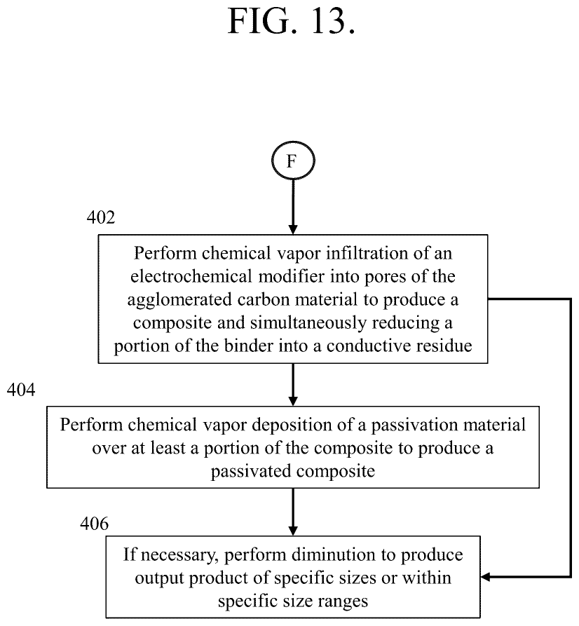

Referring to FIG. 13, in continuance from the process 300 of FIG. 4, at a block 402, CVI is performed on any of the agglomerated carbon particles created as described in FIGS. 5-9. CVI causes infiltration of an electrochemical modifier into pores of the agglomerated carbon material to produce a silicon-carbon composite. In various embodiments, a portion of the agglomerant is simultaneously reduced into a conductive residue. The conductive residue helps to enhance conductivity of the silicon-carbon composite. The amount of agglomerant that converts to the conductive residue may be less than 10%, 5%, 1%, or 0.5%. Non-residue portions of the agglomerant and any added solvent are decomposed and removed during the CVI process.

At a block 404, chemical vapor deposition (CV D) of a passivation material (e.g., decomposed hydrocarbon or the like) is optionally performed over at least a portion of the silicon-carbon composite to produce a passivated silicon-carbon composite. The silicon-carbon composite material can be covered in a carbonaceous layer accomplished by CV D. Methodologies for CVD generally described in the art can be applied to the composite materials disclosed herein. CV D is generally accomplished by subjecting the porous silicon-carbon composite material for a period of time at elevated temperature in the presence of a suitable deposition gas containing carbon atoms. Suitable gases in this context include, but are not limited to methane, propane, butane, cyclohexane, ethane, propylene, and acetylene. The temperature can be varied, for example between 350 to 1050 C, for example between 350 and 450 C, for example between 450 and 550 C, for example between 550 and 650 C, for example between 650 and 750 C, for example between 750 and 850 C, for example between 850 and 950 C, for example between 950 and 1050 C. The deposition time can be varied, for example between 0 and 5 min, for example between 5 and 15 min, for example between 15 and 30 min, for example between 30 and 60 min, for example between 60 and 120 min, for example between 120 and 240 min. In some embodiments, the deposition time is greater than 240 min. In certain embodiments, the deposition gas is methane and the deposition temperature is greater than or equal to 950 C. In certain embodiments, the deposition gas is propane and the deposition temperature is less than or equal to 750 C. In certain embodiments, the deposition gas is cyclohexane and the deposition temperature is greater than or equal to 800 C.

In various embodiments, at a block 406, diminution is performed after CVI or CVD. Diminution may be performed by a planetary milling device or comparable device in order to attain a desired particle size distribution.

In various embodiments, the reactor type used for the CVI process can be varied. For example, the CVI reactor can be a vibro-thermal assisted CVI (VTA-CVI) reactor. In other embodiments, the CVI reactor type can be a convection-thermal assisted CVI (CTA-CVI) reactor. In other embodiments, the CVI reactor type can be a rotating CVI kiln. In other embodiments, the CVI reactor type can be a fluidized bed CVI (FB-CVI) reactor. In the current Example, the CVI process was carried out as a batch process with a of between 1 and 6 hours. In other embodiments, the CVI process can be run as a semi-batch process. In certain other embodiments, the CVI process can be run as a continuous process.

In various embodiments, fines (i.e., material not in spec) produced during milling or another processing step may be agglomerated before going through CVI. This can greatly improve yield.

Types of CVI (fluidized bed, vibratory) allows for different packing thicknesses of the agglomerated carbon material.

In various embodiments, the volume average diameter for the agglomerated material, for example, the agglomerated porous carbon particles, is at least two times the volume average diameter of previously used porous carbon scaffold. Accordingly, this factor can be described as a dimensionless number G_{Dv50}, wherein,

$${G}_{Dv 50} = Dv 50 ( agglomerate ) / Dv 50 ( porous carbon particles )$$

The volume average diameter for both the agglomerate and the porous carbon scaffold can be measured as known in the art and described elsewhere in this disclosure.

In various embodiments, the volume average diameter for the agglomerated material divided by the volume average porous carbon particle diameter of the particulate material prior to the agglomeration step (the factor introduced above as G_{Dv50}) is at least three, for example at least four, for example at least five, or, for example at least ten. In certain embodiments, the volume average diameter for the agglomerated material is at least 100 times the volume average porous carbon particle diameter. In other embodiments, the volume average diameter for the agglomerated material is at least 1000 times the volume average porous carbon particle diameter. In yet other embodiments, the volume average diameter for the agglomerated material is at least 10000 times the volume average porous carbon particle diameter. In yet other embodiments, the volume average diameter for the agglomerated material is at least 100000 times the volume average porous carbon particle diameter.

The effect of the agglomerate particle size exceeding the carbon scaffold particle size is multifold, including: (i) reducing diffusional limitations for the CVI reaction in terms of access of the silane precursor gas penetrating into the porous carbon particles and (ii) improving the handling and flow properties of the material intended for CVI processing to allow for additional CVI reactor types and improved CVI processing.

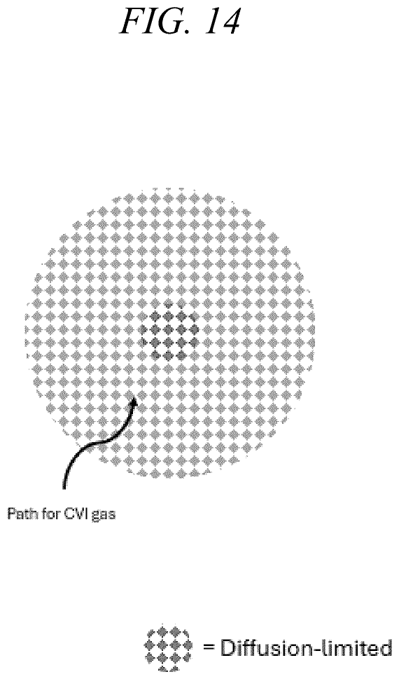

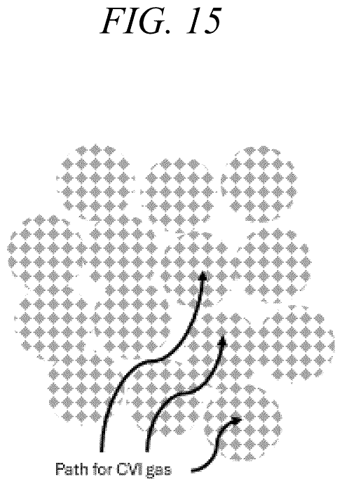

The CVI reaction for the porous carbon scaffold may be limited. For example, as illustrated in FIG. 14, the rate of CVI precursor gas consumption due to the CVI reaction may exceed the rate of diffusion of CVI precursors gas to the center of the porous carbon scaffold particle. As illustrated in FIG. 15, this is reduced or removed when conducting the CVI reaction on the agglomerated carbon particles. In this case for CVI employing the agglomerate, the diffusional limitations as the CVI percussors gas travels to the center of the agglomerate is drastically reduced since in this case the CVI precursor gas is diffusing in the intra-agglomerate porosity, which is predominantly microporous, rather than the case for CVI reaction of individual porous particles, wherein CVI precursor gas is diffusion in the intra-particle porosity, which comprises micro- and mesoporosity. In effect, as the porous carbon particle size is increased, it becomes increasingly difficult to achieve diffusion of silane precursor gas to the center of the porous carbon particle, and this limitation is removed, or at least ameliorated, by conducting CVI on agglomerates of the porous carbon particles.

Effectively, conducting the CVI process on agglomerated porous carbon particles allows for CVI processing of larger-sized particles, which would otherwise be problematic for CVI process for the non-agglomerated porous carbon particles due to the diffusional limitations for the silicon precursor gas.

In various embodiments, it is desirable to keep G_{Dv50} within a certain range. At a lower limit of G_{Dv50}, the benefits of agglomerates with regards to CVI process is minimized, and at a higher limit of G_{Dv50}, there is observed a diminishing return on the benefit, as well as potential for eventually reaching a limitation for the silicon precursor gas to permeate to the center of the agglomerate. According, in such embodiment, the value of G_{Dv50} is between 2 to 100,000. For example, in some embodiments, G_{Dv50} is between 5 to 10,000, or between 10 to 10,000 or beteem 10 and 1,000. In other embodiments, G_{Dv50} is between 2 to 100, or between 5 and 100, or between 10 and 100.

In a related embodiment, the CVI process may have limitations with decreasing porous carbon scaffold total pore volume. During the CVI reaction, there is a decrease in CVI precursor gas concentration with increasing penetration into the center of the porous carbon particle due to intra-particle diffusional limitations within the limited intra-particle porosity that is predominantly micro- and/or mesoporous.

This limitation can be removed by conducting the CVI reaction on an agglomerate of porous carbon particles. In this case for CVI employing the agglomerate, the diffusional limitations as the CVI percussors gas travels to the center of the agglomerate is drastically reduced since in this case the CVI precursor gas is diffusing in the intra-agglomerate porosity, which is predominantly microporous, rather than the case for CVI reaction of individual porous particles, wherein CVI precursor gas is diffusing into the intra-particle porosity, which comprises micro- and mesoporosity.

In various embodiments, the total inter-particle agglomerate pore volume is comparable to the porous carbon particles. This volume average diameter can be measured as known in the art and described elsewhere in this disclosure. Accordingly, this factor can be described as a dimensionless number G_{PV} as follows:

G_{PV}=Inter-particle volume (agglomerate)/Pore volume (porous carbon particles)

In various embodiments, the inter-particle volume for the agglomerate divided by the pore volume of the particulate material prior to the agglomeration step (the factor introduced above as G_{PV}) is between 0.1 to 10, or between 0.4 to 5, or between 0.4 and 2, or between 0.5 and 2, or between 0.4 and 1.5, or between 0.5 and 1.

In various embodiments, G_{PV} is greater than 0.1, for example greater than 0.2, for example greater than 0.5, for example greater than 1.0. In certain embodiments, G_{PV} is greater than 2, for example is greater than 5, for example is greater than 10. In certain embodiments, G_{PV} is greater than 100.

### 6. Physio- and Electrochemical Properties of Silicon-Carbon Composite

While not wishing to be bound by theory, it is believed that the nano sized silicon achieved as a result of filling in certain, desired pore volume structure of the porous carbon scaffold (for instance, silicon filling pores in the range of 5 to 1000 nm, or other range as disclosed elsewhere herein), along with the advantageous properties of the other components of the composite, including low surface area, low pycnometry density, yield composite materials having different and advantageous properties, for instance electrochemical performance when the composite includes an anode of a lithium-ion energy storage device.

In certain embodiments, the embedded silicon particles embedded within the composite comprise nano-sized features. The nano-sized features can have a characteristic length scale of preferably less than 1 μm, preferably less than 300 nm, preferably less than 150 nm, preferably less than 100 μm, preferably less than 50 nm, preferably less than 30 nm, preferably less than 15 nm, preferably less than 10 nm, preferably less than 5 nm.

In certain embodiments, the silicon embedded within the composite is spherical in shape. In certain other embodiments, the porous silicon particles are non-spherical, for example rod-like, or fibrous in structure. In some embodiments, the silicon exists as a layer coating the inside of pores within the porous carbon scaffold. The depth of this silicon layer can vary, for example the depth can between 5 nm and 10 nm, for example between 5 nm and 20 nm, for example between 5 nm and 30 nm, for example between 5 nm and 33 nm, for example between 10 nm and 30 nm, for example between 10 nm and 50 nm, for example between 10 nm and 100 nm, for example between 10 and 150 nm, for example between 50 nm and 150 nm, for example between 100 and 300 nm, for example between 300 and 1000 nm.

In some embodiments, the silicon embedded within the composite is nano sized, and resides within pores of the porous carbon scaffold. For example, the embedded silicon can be impregnated, deposited by CVI, or other appropriate process into pores within the porous carbon particle comprising pore sizes between 5 and 1000 nm, for example between 10 and 500 nm, for example between 10 and 200 nm, for example between 10 and 100 nm, for example between 33 and 150 nm, for example between and 20 and 100 nm. Other ranges of carbon pores sizes with regards to fractional pore volume, whether micropores, mesopores, or macropores, are also envisioned.

In some embodiments, the carbon scaffold pore volume distribution can be described as the number or volume distribution of pores as determined as known in the art based on gas sorption analysis, for example nitrogen gas sorption analysis. In some embodiments the pore size distribution can be expressed in terms of the pore size at which a certain fraction of the total pore volume resides at or below. For example, the pore size at which 10% of the pores reside at or below can be expressed at DPv10.

The DPv10 for the porous carbon scaffold or the agglomerated carbon particles can vary, for example DPv10 can be between 0.01 nm and 100 nm, for example between 0.1 nm and 100 nm, for example between 1 nm and 100 nm, for example between 1 nm and 50 nm, for example between 1 nm and 40 nm, for example between 1 nm and 30 nm, for example between 1 nm and 10 nm, for example between 1 nm and 5 nm.

The DPv50 for the porous carbon scaffold or the agglomerated carbon particles can vary, for example DPv50 can be between 0.01 nm and 100 nm, for example between 0.1 nm and 100 nm, for example between 1 nm and 100 nm, for example between 1 nm and 50 nm, for example between 1 nm and 40 nm, for example between 1 nm and 30 nm, for example between 1 nm and 10 nm, for example between 1 nm and 5 nm. In other embodiments, the DPv50 is between 2 and 100, for example between 2 and 50, for example between 2 and 30, for example between 2 and 20, for example between 2 and 15, for example between 2 and 10.

The DPv90 for the porous carbon scaffold or the agglomerated carbon particles can vary, for example DPv90 can be between 0.01 nm and 100 nm, for example between 0.1 nm and 100 nm, for example between 1 nm and 100 nm, for example between 1 nm and 50 nm, for example between 1 nm and 50 nm, for example between 1 nm and 40 nm, for example between 1 nm and 30 nm, for example between 1 nm and 10 nm, for example between 1 nm and 5 nm. In other embodiments, the DPv50 is between 2 nm and 100 nm, for example between 2 nm and 50 nm, for example between 2 nm and 30 nm, for example between 2 nm and 20 nm, for example between 2 nm and 15 nm, for example between 2 nm and 10 nm.

In some embodiments, the DPv90 is less than 100 nm, for example less than 50 nm, for example less than 40 nm, for example less than 30 nn, for example less than 20 nn, for example less than 15 nm, for example less than 10 nm. In some embodiments, the carbon scaffold comprises a pore volume with greater than 70% micropores (and DPv90 less than 100 nm, for example DPv90 less than 50 nm, for example DPv90 less than 40 nm, for example DPv90 less than 30 nm, for example DPv90 less than 20 nm, for example DPv90 less than 15 nm, for example DPv90 less than 10 nm, for example DPv90 less than 5 nm, for example DPv90 less than 4 nm, for example DPv90 less than 3 nm. In other embodiments, the carbon scaffold or agglomerated carbon particles include a pore volume with greater than 80% micropores and DPv90 less than 100 nm, for example DPv90 less than 50 nm, for example DPv90 less than 40 nm, for example DPv90 less than 30 nm, for example DPv90 less than 20 nm, for example DPv90 less than 15 nm, for example DPv90 less than 10 nm, for example DPv90 less than 5 nm, for example DPv90 less than 4 nm, for example DPv90 less than 3 nm.

The DPv99 for the porous carbon scaffold or the agglomerated carbon particles can vary, for example DPv99 can be between 0.01 nm and 1000 nm, for example between 0.1 nm and 1000 nm, for example between 1 nm and 500 nm, for example between 1 nm and 200 nm, for example between 1 nm and 150 nm, for example between 1 nm and 100 nm, for example between 1 nm and 50 nm, for example between 1 nm and 20 nm. In other embodiments, the DPv99 is between 2 nm and 500 nm, for example between 2 nm and 200 nm, for example between 2 nm and 150 nm, for example between 2 nm and 100 nm, for example between 2 nm and 50 nm, for example between 2 nm and 20 nm, for example between 2 nm and 15 nm, for example between 2 nm and 10 nm.

Embodiments of the composite with extremely durable intercalation of lithium disclosed herein improve the properties of any number of electrical energy storage devices, for example lithium-ion batteries. In some embodiments, the silicon-carbon composite disclosed herein exhibits a Z less than 10, for example a Z less than 5, for example a Z less than 4, for example a Z less than 3, for example a Z less than 2, for example a Z less than 1, for example a Z less than 0.1, for example a Z less than 0.01, for example a Z less than 0.001. In certain embodiments, the Z is zero.

In various embodiments, the silicon-carbon composite includes desireably low Z in combination with another desired physicochemical and/or electrochemical property or in combination with more than one other desired physicochemical and/or electrochemical properties. Table 1 provides a description of certain embodiments for combination of properties for the silicon-carbon composite.

TABLE 1
Embodiments for silicon-carbon composite
with embodied properties.

| | In some embodiments the |
|---|---|
| | silicon-Carbon composite includes . . . |
| Z | <10, <5, <4, <3, <2, <1, <0.1, <0.01, <0.01, 0 |
| Surface Area | <100 m²/g, <50 m²/g, <30 m²/g, <20 m²/g, |
| | <10 m²/g, <5 m²/g, <4 m²/g, <3 m²/g, |
| | <2 m²/g, <1 m²/g; |
| First Cycle | >75%, >80%, >85%, >90%, >91%, >92%, >93%, |
| Efficiency | >94%, >95%, >96%, >97%, >98%, >99%; |
| Reversible | >1300 mAh/g, >1600 mAh/g, >1700 mAh/g, |
| Capacity | >1800 mAh/g, >1900 mAh/g, >2000 mAh/g, |
| | >2100 mAh/g, >2200 mAh/g, >2300 mAh/g, |
| | >2400 mAh/g, >2500 mAh/g, >2600 mAh/g, |
| | >2700 mAh/g, >2800 mAh/g, >2900 mAh/g, |
| | >3000 mAh/g; and/or |
| Silicon | 10%-90%, 15-85%, 20%-80%, 30%-70%, 40%-60%. |
| Content | |
| by weight | |

According to Table 1, the silicon-carbon composite may comprise combinations of various properties. For example, the silicon-carbon composite may comprise a Z less than 10, surface area less than 100 m²/g, a first cycle efficiency greater than 80%, and a reversible capacity of at least 1300 mA h/g. For example, the silicon-carbon composite may comprise a Z less than 10, surface area less than 100 m²/g, a first cycle efficiency greater than 80%, and a reversible capacity of at least 1600 mA h/g. For example, the silicon-carbon composite may comprise a Z less than 10, surface area less than 20 m²/g, a first cycle efficiency greater than 85%, and a reversible capacity of at least 1600 mA h/g. For example, the silicon-carbon composite may comprise a Z less than 10, surface area less than 10 m²/g, a first cycle efficiency greater than 85%, and a reversible capacity of at least 1600 mA h/g. For example, the silicon-carbon composite may comprise a Z less than 10, surface area less than 10 m²/g, a first cycle efficiency greater than 90%, and a reversible capacity of at least 1600 mA h/g. For example, the silicon-carbon composite may comprise a Z less than 10, surface area less than 10 m²/g, a first cycle efficiency greater than 90%, and a reversible capacity of at least 1800 mA h/g.

The silicon-carbon composite can comprise a combination of the aforementioned properties, in addition to also comprising a carbon scaffold comprising properties also described within this proposal. Accordingly, Table 2 provides a description of certain embodiments for combination of properties for the silicon-carbon composite.

TABLE 2
Embodiments for silicon-carbon composite
with embodied properties.

| | In some embodiments the |
|---|---|
| | silicon-carbon composite includes . . . |
| Z | <10, <5, <4, <3, <2, <1, <0.1, <0.01, <0.01, 0 |
| Surface Area | <100 m²/g, <50 m²/g, <30 m²/g, <20 m²/g, <10 m²/g, |
| | <5 m²/g, <4 m²/g, <3 m²/g, <2 m²/g, <1 m²/g; |
| First Cycle | >75%, >80%, >85%, >90%, >91%, >92%, >93%, |
| Efficiency | >94%, >95%, >96%, >97%, >98%, >99%; |
| Reversible | >1300 mAh/g, >1600 mAh/g, >1700 mAh/g, |
| Capacity | >1800 mAh/g, >1900 mAh/g, >2000 mAh/g, |
| | >2100 mAh/g, >2200 mAh/g, >2300 mAh/g, |
| | >2400 mAh/g, >2500 mAh/g, >2600 mAh/g, |
| | >2700 mAh/g, >2800 mAh/g, >2900 mAh/g, |
| | >3000 mAh/g; |
| Silicon Content | 10%-90%, 15-85%, 20%-80%, 30%-70%, 40%-60%; |
| by weight | |
| Carbon | 0.1-1.5 cm³/g, 0.2-1.2 cm³/g, 0.3-1.1 cm³/g, |
| Scaffold | 0.4-1.0 cm³/g, 0.4-1.0 cm³/g, 0.5-1.0 cm³/g, |
| pore volume | 0.6-1.0 cm³/g, 0.5-0.9 cm³/g, 0.4-1.0 cm³/g, |
| | >0.1 cm³/g, >0.2 cm³/g, >0.4 cm³/g, |
| | >0.6 cm³/g, >0.8 cm³/g; |
| % silicon | 15%-25%, 25%-35%, 20%-40%, 25%-50%, |
| content | 30%-70%, 30%-60%, 60%-80%, 80%-100%; |
| Scaffold pore | <1 nm, 1-5 nm, 5-1000 nm, 10-500 nm, 10-200 nm, |
| size range | 10-100 nm, 33-150 nm, 20-100 nm; and/or |
| Percentage of | >20%/>30%/>30%, <10/>30/>30, <5/>30/>30, |
| microporosity/ | <5/>40/>40, <1/>40/>40, <10/>70/>20, <10/>20/>70, |
| mesoporosity/ | >10/>10/>80, <10/>80/>10, <5/>70/>20, <5/>20/>70, |
| macroporosity | <5/>5/>80, <5/>80/>10, >80%/<20%/<20%, |
| expressed as | >70/<30/<10, >70/<30/<5, >70/<20/<10, >70/<10/<10, |
| percentage of | >70/<10/<5, >70/<5/<5, >80/<20/<10, >80/<20/<5, |
| total pore | >80/<20/<1, >80/<10/<10, >80/<10/<5, >80/<10/<1, |
| volume | >90/<10/<10, >90/<10/<5, >90/<10/<1, >90/<5/<1, |
| | >95/<5/<5, >90/<5/<1 |

As used in herein, the percentage “microporosity,” “mesoporosity” and “macroporosity” refers to the percent of micropores, mesopores and macropores, respectively, as a percent of total pore volume. For example, a carbon scaffold having 90% microporosity is a carbon scaffold where 90% of the total pore volume of the carbon scaffold is formed by micropores.

According to Table 2, the silicon-carbon composite may comprise

combinations of various properties. For example, the silicon-carbon composite may comprise a Z less than 10, surface area less than 100 m²/g, a first cycle efficiency greater than 80%, a reversible capacity of at least 1600 mA h/g, a silicon content of 15%-85%, a carbon scaffold total pore volume of 0.2-1.2 cm³/g wherein the scaffold or agglomerated carbon particles pore volume includes >80% micropores, <20% mesopores, and <10% macropores. For example, the silicon-carbon composite may comprise a Z less than 10, surface area less than 20 m²/g, a first cycle efficiency greater than 85%, and a reversible capacity of at least 1600 mA h/g, a silicon content of 15%-85%, a carbon scaffold total pore volume of 0.2-1.2 cm³/g wherein the scaffold or agglomerated carbon particles pore volume includes >80% micropores, <20% mesopores, and <10% macropores. For example, the silicon-carbon composite may comprise a Z less than 10, surface area less than 10 m²/g, a first cycle efficiency greater than 85%, and a reversible capacity of at least 1600 mA h/g, a silicon content of 15%-85%, a carbon scaffold total pore volume of 0.2-1.2 cm³/g wherein the scaffold or agglomerated carbon particles pore volume includes >80% micropores, <20% mesopores, and <10% macropores. For example, the silicon-carbon composite may comprise a Z less than 10, surface area less than 10 m²/g, a first cycle efficiency greater than 90%, and a reversible capacity of at least 1600 mA h/g, a silicon content of 15%-85%, a carbon scaffold total pore volume of 0.2-1.2 cm³/g wherein the scaffold or agglomerated carbon particles pore volume includes >80% micropores, <20% mesopores, and <10% macropores. For example, the silicon-carbon composite may comprise a Z less than 10, surface area less than 10 m²/g, a first cycle efficiency greater than 90%, and a reversible capacity of at least 1800 mA h/g, a silicon content of 15%-85%, a carbon scaffold total pore volume of 0.2-1.2 cm³/g wherein the scaffold or agglomerated carbon particles pore volume includes >80% micropores, <20% mesopores, and <10% macropores.

Without being bound by theory, the filling of silicon within the pores of the porous carbon traps porosity within the porous carbon scaffold particle, resulting in inaccessible volume, for example volume that is inaccessible to nitrogen gas. Accordingly, the silicon-carbon composite material may exhibit a pycnometry density of less than 2.1 g/cm3, for example less than 2.0 g/cm3, for example less than 1.9 g/cm3, for example less than 1.8 g/cm3, for example less than 1.7 g/cm3, for example less than 1.6 g/cm3, for example less than 1.4 g/cm3, for example less than 1.2 g/cm3, for example less than 1.0 g/cm3.

In some embodiments, the silicon-carbon composite material may exhibit a pycnometry density between 1.7 g/cm³ and 2.1 g/cm³, for example between 1.7 g/cm³ and 1.8 g/cm³, between 1.8 g/cm³ and 1.9 g/cm³, for example between 1.9 g/cm³ and 2.0 g/cm³, for example between 2.0 g/cm³ and 2.1 g/cm³. In some embodiments, the silicon-carbon composite material may exhibit a pycnometry density between 1.8 g/cm³ and 2.1 g/cm³. In some embodiments, the silicon-carbon composite material may exhibit a pycnometry density between 1.8 g/cm³ and 2.0 g/cm³. In some embodiments, the silicon-carbon composite material may exhibit a pycnometry density between 1.9 g/cm³ and 2.1 g/cm³.

The pore volume of the composite material exhibiting extremely durable intercalation of lithium can range between 0.01 cm³/g and 0.2 cm³/g. In certain embodiments, the pore volume of the composite material can range between 0.01 cm³/g and 0.15 cm³/g, for example between 0.01 cm³/g and 0.1 cm³/g, for example between 0.01 cm³/g and 0.05 cm³/g.

The particle size distribution of the composite material exhibiting extremely durable intercalation of lithium is important to both determine power performance as well as volumetric capacity. As the packing improves, the volumetric capacity may increase. In one embodiment the distributions are either Gaussian with a single peak in shape, bimodal, or polymodal (>2 distinct peaks, for example trimodal). The properties of particle size of the composite can be described by the D0 (smallest particle in the distribution), Dv50 (average particle size) and Dv100 (maximum size of the largest particle). The optimal combination of particle packing and performance will be some combination of the size ranges below. The particle size reduction in the such embodiments can be carried out as known in the art, for example by jet milling in the presence of various gases including air, nitrogen, argon, helium, supercritical steam, and other gases known in the art.

In one embodiment the Dv0 of the composite material can range from 1 nm to 5 microns. In another embodiment the Dv0 of the composite ranges from 5 nm to 1 micron, for example 5-500 nm, for example 5-100 nm, for example 10-50 nm. In another embodiment the Dv0 of the composite ranges from 500 nm to 2 microns, or 750 nm to 1 μm, or 1-2 μm. In other embodiments, the Dv0 of the composite ranges from 2-5 μm, or >5 μm.

In some embodiments the Dv50 of the composite material ranges from 5 nm to 20 μm. In other embodiments the Dv50 of the composite ranges from 5 nm to 1 μm, for example 5-500 nm, for example 5-100 nm, for example 10-50 nm. In another embodiment the Dv50 of the composite ranges from 500 nm to 2 μm, 750 nm to 1 μm, 1-2 μm. In still another embodiment, the Dv50 of the composite ranges from 1 to 1000 μm, for example from 1-100 μm, for example from 1-10 μm, for example 2-20 μm, for example 3-15 μm, for example 4-8 μm. In certain embodiments, the Dv50 is >20 μm, for example >50 μm, for example >100 μm. In certain embodiments, the Dv50 of the composite ranges between 100 μm and 500 μm, for example between 100 μm and 1 mm, for example between 1 mm and 1 cm, for example between 1 cm and 2 cm, for example between 1 cm and 5 cm.

The span (Dv50)/(Dv90−Dv10), wherein Dv10, Dv50 and Dv90 represent the particle size at 10%, 50%, and 90% of the volume distribution, can be varied from example from 100 to 10, from 10 to 5, from 5 to 2, from 2 to 1; in some embodiments the span can be less than 1. In certain embodiments, the composite comprising carbon and porous silicon material particle size distribution can be multimodal, for example, bimodal, or trimodal.

The surface functionality of the presently disclosed the composite material exhibiting extremely durable intercalation of lithium may be altered to obtain the desired electrochemical properties. One property which can be predictive of surface functionality is the pH of the composite materials. The presently disclosed composite materials comprise pH values ranging from less than 1 to about 14, for example less than 5, from 5 to 8 or greater than 8. In some embodiments, the pH of the composite materials is less than 4, less than 3, less than 2 or even less than 1. In other embodiments, the pH of the composite materials is between about 5 and 6, between about 6 and 7, between about 7 and 8 or between 8 and 9 or between 9 and 10. In still other embodiments, the pH is high and the pH of the composite materials ranges is greater than 8, greater than 9, greater than 10, greater than 11, greater than 12, or even greater than 13.

The silicon-carbon composite material may comprise varying amounts of carbon, oxygen, hydrogen and nitrogen as measured by gas chromatography CHNO analysis. In one embodiment, the carbon content of the composite is greater than 98 wt. % or even greater than 99.9 wt % as measured by CHNO analysis. In another embodiment, the carbon content of the silicon-carbon composite ranges from about 10-90%, for example 20-80%, for example 30-70%, for example 40-60%.

In some embodiments, silicon-carbon composite material includes a nitrogen content ranging from 0-90%, for example 0.1-1%, for example 1-3%, for example 1-5%, for example 1-10%, for example 10-20%, for example 20-30%, for example 30-90%.

In some embodiments, the oxygen content ranges from 0-90%, for example 0.1-1%, for example 1-3%, for example 1-5%, for example 1-10%, for example 10-20%, for example 20-30%, for example 30-90%.

The silicon-carbon composite material may also incorporate an electrochemical modifier selected to optimize the electrochemical performance of the non-modified composite. The electrochemical modifier may be incorporated within the pore structure and/or on the surface of the porous carbon scaffold, within the embedded silicon, or within the final layer of carbon, or conductive polymer, coating, or incorporated in any number of other ways. For example, in some embodiments, the composite materials comprise a coating of the electrochemical modifier (e.g., silicon or Al₂O₃) on the surface of the carbon materials. In some embodiments, the composite materials comprise greater than about 100 ppm of an electrochemical modifier. In certain embodiments, the electrochemical modifier is selected from iron, tin, silicon, nickel, aluminum and manganese.

In certain embodiments, the electrochemical modifier includes an element with the ability to lithiate from 3 to 0 V versus lithium metal (e.g., silicon, tin, sulfur). In other embodiments, the electrochemical modifier includes metal oxides with the ability to lithiate from 3 to 0 V versus lithium metal (e.g., iron oxide, molybdenum oxide, titanium oxide). In still other embodiments, the electrochemical modifier includes elements which do not lithiate from 3 to 0 V versus lithium metal (e.g., aluminum, manganese, nickel, metal-phosphates). In yet other embodiments, the electrochemical modifier includes a non-metal element (e.g., fluorine, nitrogen, hydrogen). In still other embodiments, the electrochemical modifier includes any of the foregoing electrochemical modifiers or any combination thereof (e.g., tin-silicon, nickel-titanium oxide).

The electrochemical modifier may be provided in any number of forms. For example, in some embodiments the electrochemical modifier includes a salt. In other embodiments, the electrochemical modifier includes one or more elements in elemental form, for example elemental iron, tin, silicon, nickel or manganese. In other embodiments, the electrochemical modifier includes one or more elements in oxidized form, for example iron oxides, tin oxides, silicon oxides, nickel oxides, aluminum oxides or manganese oxides.

The electrochemical properties of the composite material can be modified, at least in part, by the amount of the electrochemical modifier in the material, wherein the electrochemical modifier is an alloying material such as silicon, tin, indium, aluminum, germanium, gallium. Accordingly, in some embodiments, the composite material includes at least 0.10%, at least 0.25%, at least 0.50%, at least 1.0%, at least 5.0%, at least 10%, at least 25%, at least 50%, at least 75%, at least 90%, at least 95%, at least 99% or at least 99.5% of the electrochemical modifier.

The particle size of the composite material may expand upon lithiation as compared to the non-lithiated state. For example, the expansion factor, defined as ratio of the average particle size of particles of composite material comprising a porous silicon material upon lithiation divided by the average particle size under non-lithiated conditions. As described in the art, this expansion factor can be relatively large for previously known, non-optimal silicon-containing materials, for example about 4× (corresponding to a 400% volume expansion upon lithiation). The current inventors have discovered composite materials comprising a porous silicon material that can exhibit a lower extent of expansion, for example, the expansion factor can vary from 3.5 to 4, from 3.0 to 3.5, from 2.5 to 3.0, from 2.0 to 2.5, from 1.5 to 2.0, from 1.0 to 1.5.

It is envisioned that composite materials in certain embodiments will comprise a fraction of trapped pore volume, namely, void volume non-accessible to nitrogen gas as probed by nitrogen gas sorption measurement. Without being bound by theory, this trapped pore volume is important in that it provides volume into which silicon can expand upon lithiation.

In certain embodiments, the ratio of trapped void volume to the silicon volume comprising the composite particle is between 0.1:1 and 10:1. For example, the ratio of trapped void volume to the silicon volume comprising the composite particle is between 1:1 and 5:1, or 5:1 to 10:1. In embodiments, the ratio of ratio trapped void volume to the silicon volume comprising the composite particle is between 2:1 and 5:1, or about 3:1, in order to efficiently accommodate the maximum extent of expansion of silicon upon lithiation.

In certain embodiments, the electrochemical performance of the composite disclosed herein is tested in a half-cell; alternatively, the performance of the composite with extremely durable intercalation of lithium disclosed herein is tested in a full cell, for example a full cell coin cell, a full cell pouch cell, a prismatic cell, or other battery configurations known in the art. The anode composition comprising the composite with extremely durable intercalation of lithium disclosed herein can further comprise various species, as known in the art. Additional formulation components include, but are not limited to, conductive additives, such as conductive carbons such as Super C45, Super P, Ketjenblack carbons, and the like, conductive polymers and the like, binders such as styrene-butadiene rubber sodium carboxymethylcellulose (SBR-Na-CMC), polyvinylidene difluoride (PVDF), polyimide (PI), polyacrylic acid (PAA) and the like, and combinations thereof. In certain embodiments, the binder can comprise a lithium-ion as counter ion.

Other species comprising the electrode are known in the art. The % of active material in the electrode by weight can vary, for example between 1 and 5%, for example between 5 and 15%, for example between 15 and 25%, for example between 25 and 35%, for example between 35 and 45%, for example between 45 and 55%, for example between 55 and 65%, for example between 65 and 75%, for example between 75 and 85%, for example between 85 and 95%. In some embodiments, the active material includes between 80 and 95% of the electrode. In certain embodiments, the amount of conductive additive in the electrode can vary, for example between 1 and 5%, between 5 and 15%, for example between 15 and 25%, for example between 25 and 35%. In some embodiments, the amount of conductive additive in the electrode is between 5 and 25%. In certain embodiments, the amount of binder can vary, for example between 1 and 5%, between 5 and 15%, for example between 15 and 25%, for example between 25 and 35%. In certain embodiments, the amount of conductive additive in the electrode is between 5 and 25%.

The silicon-carbon composite material may be prelithiated, as known in the art. In certain embodiments, the prelithiation is achieved electrochemically, for example in a half cell, prior to assembling the lithiated anode comprising the porous silicon material into a full cell lithium-ion battery. In certain embodiments, prelithiation is accomplished by doping the cathode with a lithium-containing compound, for example a lithium containing salt. Examples of suitable lithium salts in this context include, but are not limited to, dilithium tetrabromonickelate(II), dilithium tetrachlorocuprate (II), lithium azide, lithium benzoate, lithium bromide, lithium carbonate, lithium chloride, lithium cyclohexanebutyrate, lithium fluoride, lithium formate, lithium hexafluoroarsenate (V), lithium hexafluorophosphate, lithium hydroxide, lithium iodate, lithium iodide, lithium metaborate, lithium perchlorate, lithium phosphate, lithium sulfate, lithium tetraborate, lithium tetrachloroaluminate, lithium tetrafluoroborate, lithium thiocyanate, lithium trifluoromethanesulfonate, lithium trifluoromethanesulfonate, and combinations thereof.

The anode comprising the silicon-carbon composite material can be paired with various cathode materials to result in a full cell lithium-ion battery. Examples of suitable cathode materials are known in the art. Examples of such cathode materials include, but are not limited to LiCoO₂ (LCO), LiNi_{0.8}Co_{0.15}Al_{0.05}O₂ (NCA), LiNi_{1/3}Co_{1/3}Mn_{1/3}O₂ (NMC), LiMn₂O₄ and variants (LMO), and LiFePO₄ (LFP).

For the full cell lithium-ion battery comprising an anode further comprising the silicon-carbon composite material, pairing of cathode to anode can be varied. For example, the ratio of cathode-to-anode capacity can vary from 0.7 to 1.3. In certain embodiments, the ratio of cathode-to-anode capacity can vary from 0.7 to 1.0, for example from 0.8 to 1.0, for example from 0.85 to 1.0, for example from 0.9 to 1.0, for example from 0.95 to 1.0. In other embodiments, the ratio of cathode-to-anode capacity can vary from 1.0 to 1.3, for example from 1.0 to 1.2, for example from 1.0 to 1.15, for example from 1.0 to 1.1, for example from 1.0 to 1.05. In yet other embodiments, the ratio of cathode-to-anode capacity can vary from 0.8 to 1.2, for example from 0.9 to 1.1, for example from 0.95 to 1.05.

For the full cell lithium-ion battery comprising an anode further comprising the silicon-carbon composite material, the voltage window for charging and discharging can be varied. In this regard, the voltage window can be varied as known in the art, depending on various properties of the lithium-ion battery. For instance, the choice of cathode plays a role in the voltage window chosen, as known in the art. Examples of voltage windows vary, for example, in terms of potential versus Li/Li+, from 2.0 V to 5.0 V, for example from 2.5 V to 4.5V, for example from 2.5V to 4.2V.

For the full cell lithium-ion battery comprising an anode further comprising the silicon-carbon composite material, the strategy for conditioning the cell can be varied as known in the art. For example, the conditioning can be accomplished by one or more charge and discharge cycles at various rate(s), for example at rates slower than the desired cycling rate. As known in the art, the conditioning process may also include a step to unseal the lithium-ion battery, evacuate any gases generated within during the conditioning process, followed by resealing the lithium-ion battery.

For the full cell lithium-ion battery comprising an anode further comprising the silicon-carbon composite material, the cycling rate can be varied as known in the art, for example, the rate can between C/20 and 20 C, for example between C10 to 10 C, for example between C/5 and 5 C. In certain embodiments, the cycling rate is C/10. In certain embodiments, the cycling rate is C/5. In certain embodiments, the cycling rate is C/2. In certain embodiments, the cycling rate is 1 C. In certain embodiments, the cycling rate is 1 C, with periodic reductions in the rate to a slower rate, for example cycling at 1 C with a C/10 rate employed every 20^{th} cycle. In certain embodiments, the cycling rate is 2 C. In certain embodiments, the cycling rate is 4 C. In certain embodiments, the cycling rate is 5 C. In certain embodiments, the cycling rate is 10 C. In certain embodiments, the cycling rate is 20 C.

The first cycle efficiency of the composite with extremely durable intercalation of lithium disclosed herein be determined by comparing the lithium inserted into the anode during the first cycle to the lithium extracted from the anode on the first cycle, prior prelithiation modification. When the insertion and extraction are equal, the efficiency is 100%. As known in the art, the anode material can be tested in a half-cell, where the counter electrode is lithium metal, the electrolyte is a 1M LiPF₆ 1:1 ethylene carbonate:diethylcarbonate (EC:DEC), using a commercial polypropylene separator. In certain embodiments, the electrolyte can comprise various additives known to provide improved performance, such as fluoroethylene carbonate (FEC) or other related fluorinated carbonate compounds, or ester co-solvents such as methyl butyrate, vinylene carbonate, and other electrolyte additives known to improve electrochemical performance of silicon-comprising anode materials.

Coulombic efficiency can be averaged, for example averaged over cycles 7 to cycle 25 when tested in a half cell. Coulombic efficiency can be averaged, for example averaged over cycles 7 to cycle 20 when tested in a half cell. In certain embodiments, the average efficiency of the composite with extremely durable intercalation of lithium is greater than 0.9, or 90%. In certain embodiments, the average efficiency is greater than 0.95, or 95%. In certain other embodiments, the average efficiency is 0.99 or greater, for example 0.991 or greater, for example 0.992 or greater, for example 0.993 or greater, for example 0.994 or greater, for example 0.995 or greater, for example 0.996 or greater, for example 0.997 or greater, for example 0.998 or greater, for example 0.999 or greater, for example 0.9991 or greater, for example 0.9992 or greater, for example 0.9993 or greater, for example 0.9994 or greater, for example 0.9995 or greater, for example 0.9996 or greater, for example 0.9997 or greater, for example 0.9998 or greater, for example 0.9999 or greater.

In still other embodiments the present disclosure provides a composite material exhibiting extremely durable intercalation of lithium, wherein when the composite material is incorporated into an electrode of a lithium-based energy storage device the composite material has a volumetric capacity at least 10% greater than when the lithium-based energy storage device includes a graphite electrode. In some embodiments, the lithium-based energy storage device is a lithium-ion battery. In other embodiments, the composite material has a volumetric capacity in a lithium-based energy storage device that is at least 5% greater, at least 10% greater, at least 15% greater than the volumetric capacity of the same electrical energy storage device having a graphite electrode. In still other embodiments, the composite material has a volumetric capacity in a lithium-based energy storage device that is at least 20% greater, at least 30% greater, at least 40% greater, at least 50% greater, at least 200% greater, at least 100% greater, at least 150% greater, or at least 200% greater than the volumetric capacity of the same electrical energy storage device having a graphite electrode.

The composite material may be prelithiated, as known in the art. These lithium atoms may or may not be able to be separated from the carbon. The number of lithium atoms to 6 carbon atoms can be calculated by techniques known to those familiar with the art:

$$\# Li = Q \times 3.6 \times MM / ( C \% \times F )$$

wherein Q is the lithium extraction capacity measured in mA h/g between the voltages of 5 mV and 2.0V versus lithium metal, MM is 72 or the molecular mass of 6 carbons, F is Faraday's constant of 96500, C % is the mass percent carbon present in the structure as measured by CHNO or XPS.

The composite material can be characterized by the ratio of lithium atoms to carbon atoms (Li:C) which may vary between about 0:6 and 2:6. In some embodiments the Li:C ratio is between about 0.05:6 and about 1.9:6. In other embodiments the maximum Li:C ratio wherein the lithium is in ionic and not metallic form is 2.2:6. In certain other embodiments, the Li:C ratio ranges from about 1.2:6 to about 2:6, from about 1.3:6 to about 1.9:6, from about 1.4:6 to about 1.9:6, from about 1.6:6 to about 1.8:6 or from about 1.7:6 to about 1.8:6. In other embodiments, the Li:C ratio is greater than 1:6, greater than 1.2:6, greater than 1.4:6, greater than 1.6:6 or even greater than 1.8:6. In even other embodiments, the Li:C ratio is about 1.4:6, about 1.5:6, about 1.6:6, about 1.6:6, about 1.7:6, about 1.8:6 or about 2:6. In a specific embodiment the Li:C ratio is about 1.78:6.

In certain other embodiments, the composite material includes an Li:C ratio ranging from about 1:6 to about 2.5:6, from about 1.4:6 to about 2.2:6 or from about 1.4:6 to about 2:6. In still other embodiments, the composite materials may not necessarily include lithium, but instead have a lithium uptake capacity (i.e., the capability to uptake a certain quantity of lithium, for example upon cycling the material between two voltage conditions (in the case of a lithium-ion half cell, an exemplary voltage window lies between 0 and 3 V, for example between 0.005 and 2.7 V, for example between 0.005 and 1 V, for example between 0.005 and 0.8 V). While not wishing to be bound by theory, it is believed the lithium uptake capacity of the composite materials contributes to their superior performance in lithium-based energy storage devices. The lithium uptake capacity is expressed as a ratio of the atoms of lithium taken up by the composite. In certain other embodiments, the composite material exhibiting extremely durable intercalation of lithium comprise a lithium uptake capacity ranging from about 1:6 to about 2.5:6, from about 1.4:6 to about 2.2:6 or from about 1.4:6 to about 2:6.

In certain other embodiments, the lithium uptake capacity ranges from about 1.2:6 to about 2:6, from about 1.3:6 to about 1.9:6, from about 1.4:6 to about 1.9:6, from about 1.6:6 to about 1.8:6 or from about 1.7:6 to about 1.8:6. In other embodiments, the lithium uptake capacity is greater than 1:6, greater than 1.2:6, greater than 1.4:6, greater than 1.6:6 or even greater than 1.8:6. In even other embodiments, the Li:C ratio is about 1.4:6, about 1.5:6, about 1.6:6, about 1.6:6, about 1.7:6, about 1.8:6 or about 2:6. In a specific embodiment the Li:C ratio is about 1.78:6.

Water gassing is a method to estimate the gas generation from SCC55 and water reaction. The method is known by those of ordinary skill in the art. Lower water gassing is better for better electrode processing and thus better electrochemical performance. In various embodiments, after CVI oxygen wt % below 3 provides a silicon-carbon composite not prone to exhibiting an exothermic reaction with air.

### EXAMPLES

Example 1. Production of silicon-carbon composite material by CVI. The properties of the carbon scaffold (Carbon Scaffold 1) employed for producing the silicon-carbon composite is presented in Table 3. Employing Carbon Scaffold 1, the silicon-carbon composite (Silicon-Carbon Composite 1) was produced by CVI as follows. A mass of 0.2 grams of amorphous porous carbon was placed into a 2 in.×2 in. ceramic crucible then positioned in the center of a horizontal tube furnace. The furnace was sealed and continuously purged with nitrogen gas at 500 cubic centimeters per minute (ccm). The furnace temperature was increased from 20° C./min to 450° C. peak temperature where it was allowed to equilibrate for 30 minutes. At this point, the nitrogen gas is shutoff and then silane and hydrogen gas are introduced at flow rates of 50 ccm and 450 ccm, respectively for a total dwell time of 30 minutes. After the dwell period, silane and hydrogen were shutoff and nitrogen was again introduced to the furnace to purge the internal atmosphere. Simultaneously the furnace heat is shutoff and allowed to cool to ambient temperature. The completed Si—C material is subsequently removed from the furnace.

TABLE 3
Description of carbon scaffold employed for Example 1.

| Carbon | Surface | Pore | | | |
|---|---|---|---|---|---|
| Scaffold | Area | Volume | % | % | % |
| # | (m²/g) | (cm³/g) | Micropores | Mesopores | Macropores |
| 1 | 1710 | 0.762 | 93.1 | 6.8 | 0.1 |

Example 2. Analysis of various silicon-composite materials. A variety of carbon scaffold materials were employed, and the carbon scaffold materials were characterized by nitrogen sorption gas analysis to determine specific surface area, total pore volume, and fraction of pore volume comprising micropores, mesopores, and macropores. The characterization data for the carbon scaffold materials is presented in Table 4, namely the data for carbon scaffold surface area, pore volume, and pore volume distribution (% micropores, % mesopores, and % macropores), all as determined by nitrogen sorption analysis.

TABLE 4
Properties of various carbon scaffold materials.

| Carbon | | Pore | | | |
|---|---|---|---|---|---|
| Scaffold | Surface | Volume | % | % | % |
| # | Area (m₂/g) | (cm₃/g) | Micropores | Mesopores | Macropores |
| 1 | 1710 | 0.762 | 93.1 | 6.8 | 0.1 |
| 2 | 1744 | 0.72 | 97.2 | 2.7 | 0.1 |
| 3 | 1581 | 0.832 | 69.1 | 30.9 | 0.1 |
| 4 | 1710 | 0.817 | 80.1 | 19.9 | 0 |
| 5 | 1835 | 0.9 | 82.2 | 17.8 | 0 |
| 6 | 1475 | 1.06 | 52.4 | 47.6 | 0 |
| 7 | 453 | 0.5 | 3.9 | 91.1 | 5.1 |
| 8 | 787 | 2.284 | 0 | 59.1 | 40.9 |
| 9 | 1713 | 0.76 | 91 | 9 | 0 |
| 10 | 1690 | 0.741 | 92.6 | 7.3 | 0.1 |
| 11 | 1918 | 0.858 | 89.9 | 10.1 | 0 |

The carbons scaffold sample as described in Table 4 were employed to produce a variety of silicon-carbon composite materials employing the CVI methodology in a static bed configuration as generally described in Example 1. These silicon-carbon samples were produced employing a range of process conditions: silane concentration 1.25% to 100%, diluent gas nitrogen or hydrogen, carbon scaffold starting mass 0.2 g to 700 g.

The surface area for the silicon-carbon composites was determined. The silicon-carbon composites were also analyzed by TGA to determine silicon content and the Z. Silicon-carbon composite materials were also tested in half-cell coin cells. The anode for the half-cell coin cell can comprise 60-90% silicon-carbon composite, 5-20% Na-CMC (as binder) and 5-20% Super C45 (as conductivity enhancer), and the electrolyte can comprise 2:1 ethylene carbonate:diethylene carbonate, 1 M LiPF6 and 10% fluoroethylene carbonate. The half-cell coin cells can be cycled at 25° C. at a rate of C/5 for 5 cycles and then cycled thereafter at C/10 rate. The voltage can be cycled between 0 V and 0.8 V, alternatively, the voltage can be cycled between 0 V and 1.5 V. From the half-cell coin cell data, the maximum capacity can be measured, as well as the average Coulombic efficiency (CE) over the range of cycles from cycle 7 to cycle 20. Physicochemical and electrochemical properties for various silicon-carbon composite materials are presented in Table 5.

TABLE 5
Properties of various silicon-carbon materials.

| Silicon- | | | | | | |
|---|---|---|---|---|---|---|
| Carbon | Carbon | Surface | Si | | Max | Average |
| Composite | Scaffold | Area | content | | Capacity | CE |
| # | # | (m²/g) | (%) | Z | (mAh/g) | (7-20) |
| 1 | 1 | 7 | 45.0 | 0.2 | 1433 | 0.9981 |
| 2 | 1 | 7 | 45.4 | 0.6 | 1545 | 0.9980 |
| 3 | 1 | 6 | 45.8 | 0.6 | 1510 | 0.9975 |
| 4 | 2 | 3.06 | 50.1 | 1.0 | 1665 | 0.9969 |
| 5 | 2 | 1.96 | 51.3 | 2.0 | 1662 | 0.9974 |
| 6 | 3 | 140 | 43.1 | 3.2 | 832 | 0.9941 |
| 7 | 2 | 1.61 | 48.7 | 2.8 | 1574 | 0.9977 |
| 8 | 2 | 2 | 48.5 | 3.0 | 1543 | 0.9972 |
| 9 | 1 | 8 | 46.3 | 0.2 | 1373 | 0.9976 |
| 10 | 4 | 44 | 51.2 | 6.2 | 1614 | 0.9975 |
| 11 | 5 | 94 | 48.9 | 6.2 | 1455 | 0.9969 |
| 12 | 6 | 61 | 52.1 | 10.6 | 2011 | 0.9869 |
| 13 | 7 | 68.5 | 34.6 | 17.2 | 1006 | 0.9909 |
| 14 | 8 | 20 | 74 | 33.5 | 2463 | 0.9717 |
| 15 | 8 | 149 | 57.7 | 34.5 | 1892 | 0.9766 |
| 16 | 8 | 61.7 | 68.9 | 38.7 | 2213 | 0.9757 |
| 17 | 9 | 11 | 46.1 | 0.8 | 1675 | 0.9990 |
| 18 | 9 | 11 | 46.7 | 2.0 | 1739 | 0.9985 |
| 19 | 9 | 15.1 | 46.8 | 1.7 | 1503 | 0.9980 |
| 20 | 9 | 4.1 | 47.9 | 4.2 | 1790 | 0.9953 |
| 21 | 9 | 5 | 48.1 | 4.6 | 1861 | 0.9962 |
| 22 | 10 | 5.1 | 44.5 | 0 | ND | ND |
| 23 | 10 | 8.4 | 43.6 | 0 | ND | ND |
| 24 | 11 | 13.6 | 45.0 | 0.92 | 1848 | Pending |

ND = not determined

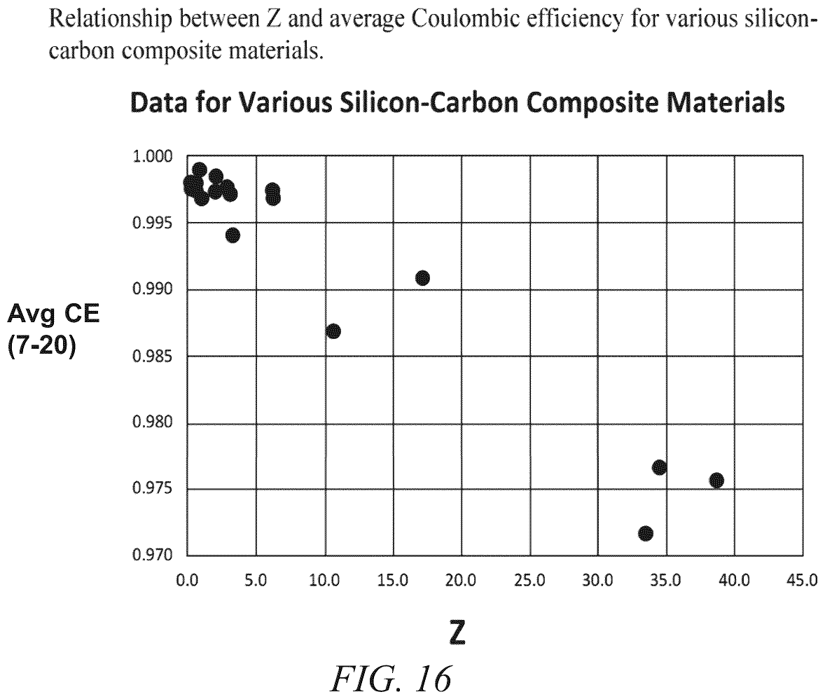

A plot of the average Coulombic efficiency as a function of the Z is presented in FIG. 16. As can be seen there was dramatic increase in the average Coulombic efficiency for silicon-carbon samples with low Z. In particular, all silicon-carbon samples with Z below 10.0 exhibited average Coulombic efficiency ≥0.9941, and all silicon-carbon samples with Z above 10 (Silicon-Carbon Composite Sample 12 through Silicon-Carbon Composite Sample 16) were observed to have average Coulombic efficiency ≤0.9909. Without being bound by theory, higher Coulombic efficiency for the silicon-carbon samples with Z<10 provides for superior cycling stability in full cell lithium-ion batteries. Further inspection of Table reveals the surprising and unexpected finding that the combination of silicon-carbon composite samples with Z<10 and also comprising carbon scaffold comprising >69.1 microporosity provides for average Coulombic efficiency ≥0.9969.

Therefore, in one embodiment, the silicon-carbon composite material includes a Z less than 10, for example less Z less than 5, for example less Z less than 3, for example less Z less than 2, for example less Z less than 1, for example less Z less than 0.5, for example less Z less than 0.1, or Z of zero.

In various embodiments, the silicon-carbon composite material includes a Z less than 10 and a carbon scaffold with >70% microporosity, for example Z less than 10 and >80% microporosity, for example Z less than 10 and >90% microporosity, for example Z less than 10 and >95% microporosity, for example Z less than 5 and >70% microporosity, for example Z less than 5 and >80% microporosity, for example Z less than 5 and >90% microporosity, for example Z less than 5 and >95% microporosity, for example Z less than 3 and >70% microporosity, for example Z less than 3 and >80% microporosity, for example Z less than 3 and >90% microporosity, for example Z less than 3 and >95% microporosity, for example Z less than 2 and >70% microporosity, for example Z less than 2 and >80% microporosity, for example Z less than 2 and >90% microporosity, for example Z less than 2 and >95% microporosity, for example Z less than 1 and >70% microporosity, for example Z less than 1 and >80% microporosity, for example Z less than 1 and >90% microporosity, for example Z less than 1 and >95% microporosity, for example Z less than 0.5 and >70% microporosity, for example Z less than 0.5 and >80% microporosity, for example Z less than 0.5 and >90% microporosity, for example Z less than 0.5 and >95% microporosity, for example Z less than 0.1 and >70% microporosity, for example Z less than 0.1 and >80% microporosity, for example Z less than 0.1 and >90% microporosity, for example Z less than 0.1 and >95% microporosity, for example Z of zero and >70% microporosity, for example Z of zero and >80% microporosity, for example Z of zero and >90% microporosity, for example Z of zero and >95% microporosity.

In various embodiments, the silicon-carbon composite material includes a Z less than 10 and a carbon scaffold with >70% microporosity, and wherein the silicon-carbon composite also includes 15%-85% silicon, and surface area less than 100 m²/g, for example Z less than 10 and >70% microporosity, and wherein the silicon-carbon composite also includes 15%-85% silicon, and surface area less than 50 m²/g, for example Z less than 10 and >70% microporosity, and wherein the silicon-carbon composite also includes 15%-85% silicon, and surface area less than 30 m²/g, for example Z less than 10 and >70% microporosity, and wherein the silicon-carbon composite also includes 15%-85% silicon, and surface area less than 10 m²/g, for example Z less than 10 and >70% microporosity, and wherein the silicon-carbon composite also includes 15%-85% silicon, and surface area less than 5 m²/g, for example Z less than 10 and >80% microporosity, and wherein the silicon-carbon composite also includes 15%-85% silicon, and surface area less than 50 m²/g, for example Z less than 10 and >80% microporosity, and wherein the silicon-carbon composite also includes 15%-85% silicon, and surface area less than 30 m²/g, for example Z less than 10 and >80% microporosity, and wherein the silicon-carbon composite also includes 15%-85% silicon, and surface area less than 10 m²/g, for example Z less than 10 and >80% microporosity, and wherein the silicon-carbon composite also includes 15%-85% silicon, and surface area less than 5 m²/g, for example Z less than 10 and >90% microporosity, and wherein the silicon-carbon composite also includes 15%-85% silicon, and surface area less than 50 m²/g, for example Z less than 10 and >90% microporosity, and wherein the silicon-carbon composite also includes 15%-85% silicon, and surface area less than 30 m²/g, for example Z less than 10 and >90% microporosity, and wherein the silicon-carbon composite also includes 15%-85% silicon, and surface area less than 10 m²/g, for example Z less than 10 and >90% microporosity, and wherein the silicon-carbon composite also includes 15%-85% silicon, and surface area less than 5 m²/g, for example Z less than 10 and >95% microporosity, and wherein the silicon-carbon composite also includes 15%-85% silicon, and surface area less than 50 m²/g, for example Z less than 10 and >95% microporosity, and wherein the silicon-carbon composite also includes 15%-85% silicon, and surface area less than 30 m²/g, for example Z less than 10 and >95% microporosity, and wherein the silicon-carbon composite also includes 15%-85% silicon, and surface area less than 10 m²/g, for example Z less than 10 and >95% microporosity, and wherein the silicon-carbon composite also includes 15%-85% silicon, and surface area less than 5 m²/g.

In various embodiments, the silicon-carbon composite material includes a Z less than 10 and a carbon scaffold with >70% microporosity, and wherein the silicon-carbon composite also includes 30%-60% silicon, and surface area less than 100 m²/g, for example Z less than 10 and >70% microporosity, and wherein the silicon-carbon composite also includes 30%-60% silicon, and surface area less than 50 m²/g, for example Z less than 10 and >70% microporosity, and wherein the silicon-carbon composite also includes 30%-60% silicon, and surface area less than 30 m²/g, for example Z less than 10 and >70% microporosity, and wherein the silicon-carbon composite also includes 30%-60% silicon, and surface area less than 10 m²/g, for example Z less than 10 and >70% microporosity, and wherein the silicon-carbon composite also includes 30%-60% silicon, and surface area less than 5 m²/g, for example Z less than 10 and >80% microporosity, and wherein the silicon-carbon composite also includes 30%-60% silicon, and surface area less than 50 m²/g, for example Z less than 10 and >80% microporosity, and wherein the silicon-carbon composite also includes 30%-60% silicon, and surface area less than 30 m²/g, for example Z less than 10 and >80% microporosity, and wherein the silicon-carbon composite also includes 30%-60% silicon, and surface area less than 10 m²/g, for example Z less than 10 and >80% microporosity, and wherein the silicon-carbon composite also includes 30%-60% silicon, and surface area less than 5 m²/g, for example Z less than 10 and >90% microporosity, and wherein the silicon-carbon composite also includes 30%-60% silicon, and surface area less than 50 m²/g, for example Z less than 10 and >90% microporosity, and wherein the silicon-carbon composite also includes 30%-60% silicon, and surface area less than 30 m²/g, for example Z less than 10 and >90% microporosity, and wherein the silicon-carbon composite also includes 30%-60% silicon, and surface area less than 10 m²/g, for example Z less than 10 and >90% microporosity, and wherein the silicon-carbon composite also includes 30%-60% silicon, and surface area less than 5 m²/g, for example Z less than 10 and >95% microporosity, and wherein the silicon-carbon composite also includes 30%-60% silicon, and surface area less than 50 m²/g, for example Z less than 10 and >95% microporosity, and wherein the silicon-carbon composite also includes 30%-60% silicon, and surface area less than 30 m²/g, for example Z less than 10 and >95% microporosity, and wherein the silicon-carbon composite also includes 30%-60% silicon, and surface area less than 10 m²/g, for example Z less than 10 and >95% microporosity, and wherein the silicon-carbon composite also includes 30%-60% silicon, and surface area less than 5 m²/g.

Example 3. dV/dQ for various silicon-composite materials. Differential capacity curve (dQ/dV vs Voltage) is often used as a non-destructive tool to understand the phase transition as a function of voltage in lithium battery electrodes (M. N. Obrovac et al. Structural Changes in Silicon A nodes during Lithium Insertion/Extraction, Electrochemical and Solid-State Letters, 7 (5) A 93-A 96 (2004); Ogata, K. et al. Revealing lithium-silicide phase transformations in nano-structured silicon-based lithium-ion batteries via in situ NMR spectroscopy. Nat. Commun. 5:3217). Differential capacity plots presented here is calculated from the data obtained using galvanostatic cycling at 0.1 C rate between 5 mV to 0.8V in a half-cell coin cell at 25° C. Typical differential capacity curve for a silicon-based material in a half-cell vs lithium can be found in many literature references (Loveridge, M. J. et al. Towards High Capacity Li-Ion Batteries Based on Silicon-Graphene Composite A nodes and Sub-micron V-doped LiFePO4 Cathodes. Sci. Rep. 6, 37787; doi: 10.1038/srep37787 (2016); M. N. Obrovac et al. Li15Si4Formation in Silicon Thin Film Negative Electrodes, Journal of The Electrochemical Society, 163 (2) A 255-A 261 (2016); Q. Pan et al. Improved electrochemical performance of micro-sized SiO-based composite anode by prelithiation of stabilized lithium metal powder, Journal of Power Sources 347 (2017) 170-177). First cycle lithiation behavior is dependent on the crystallinity of the silicon and content among other factors.

After the first cycle, previous amorphous silicon materials in the art exhibit two specific phase transition peaks in the dQ/dV vs V plot for lithiation, and correspondingly two specific phase transition peaks in the dQ/dV vs V plot for delithiation. For lithiation, one peak corresponding to lithium-poor Li—Si alloy phase occurs between 0.2-0.4 V and another peak corresponding to a lithium-rich Li—Si alloy phase occurs below 0.15 V. For delithiation, one delithiation peak corresponding to the extraction of lithium occurs below 0.4 V and another peak occurs between 0.4 V and 0.55 V. If the Li15Si4 phase is formed during lithiation, it is delithiated at ˜0.45V and appears as a very narrow sharp peak.

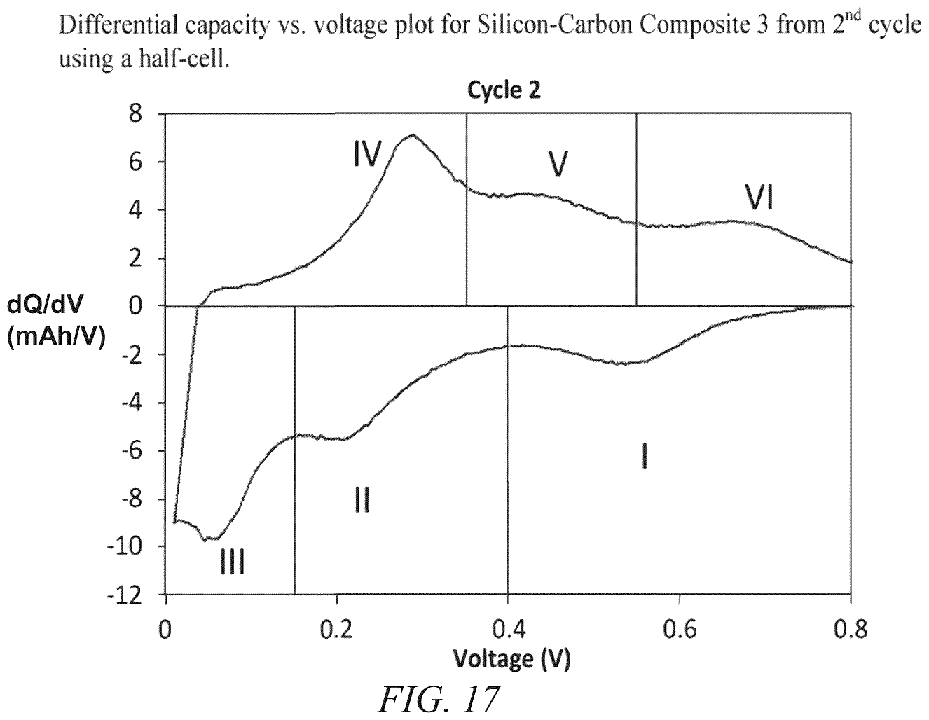

FIG. 17 depicts the dQ/dV vs Voltage curve for cycle 2 for the silicon-carbon composite material corresponding to Silicon-Carbon Composite 3 from Example 1. Silicon-Carbon Composite 3 includes a Z of 0.6. For ease of identification, the plot is divided into regimes I, II, II, IV, V, and VI. Regimes I (0.8 V to 0.4 V), II (0.4 V to 0.15 V), III (0.15 V to 0 V) comprise the lithiation potentials and Regimes IV (0 V to 0.4 V), V (0.4 V to 0.55 V), VI (0.55 V to 0.8 V) comprise the delithiation potential. As described above, previous amorphous silicon-based materials in the art exhibit phase-transition peaks for two regimes (Regime II and Regime III) in the lithiation potential and two regimes (Regime IV and Regime V) in the delithiation potentials.

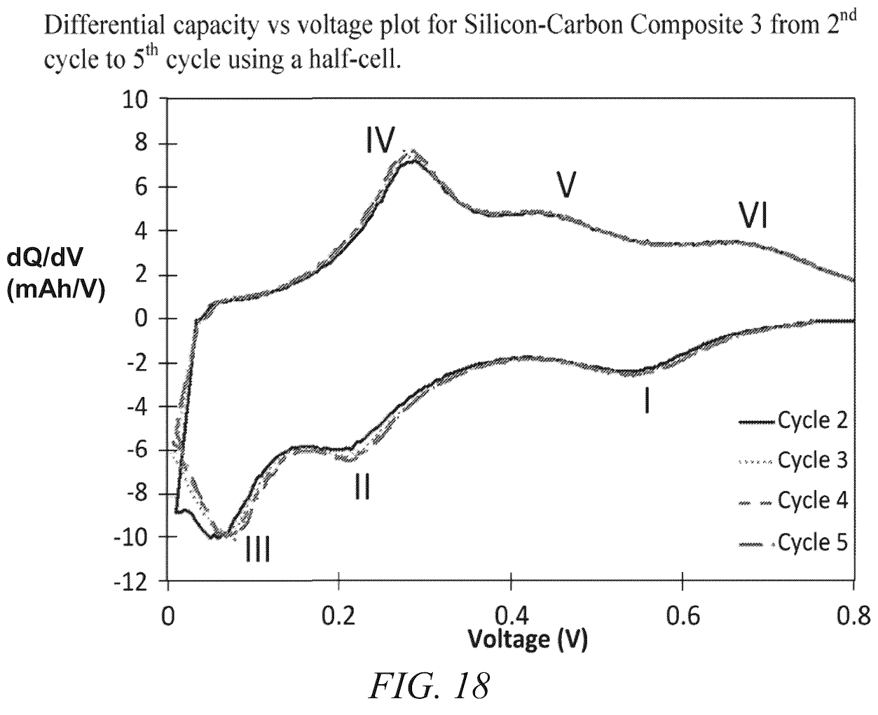

As can be seen in FIG. 17, the dQ/dV vs Voltage curve reveals surprising and unexpected result that Silicon-Carbon Composite 3, which includes a Z of 0.6, includes two additional peaks in the dQ/dV vs Voltage curve, namely Regime I in the lithiation potential and Regime VI in the delithiation potential. All 6 peaks are reversible and observed in the subsequent cycles as well, as shown in FIG. 18.

Without being bound by theory, such trimodal behavior for the dQ/dV vs V curve is novel, and likewise reflects a novel form of silicon.

Notably, the novel peaks observed in Regime I and Regime VI are more pronounced in certain scaffold matrixes and completely absent in other samples illustrating the prior art (silicon-carbon composite samples with Z>10, see explanation and table below).

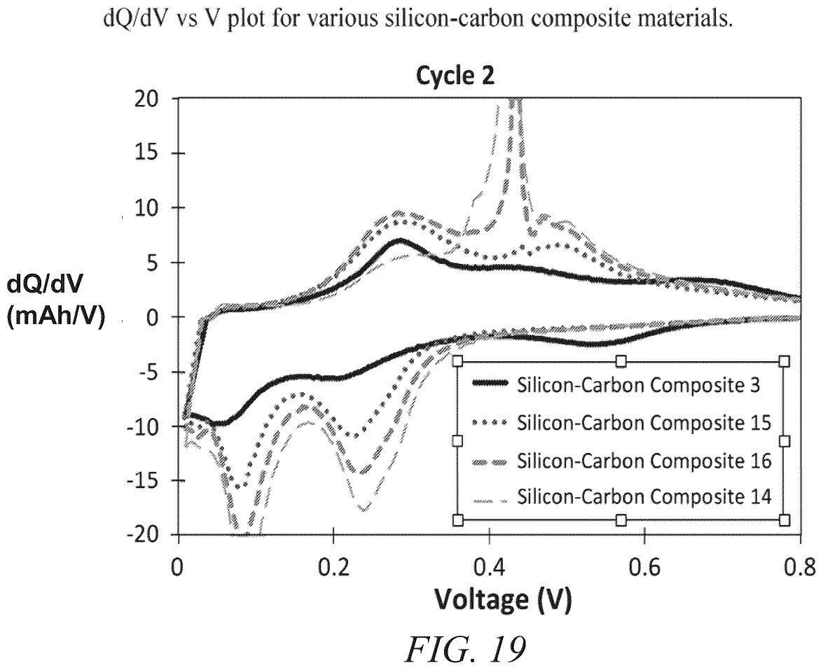

FIG. 19 presents the dQ/dV vs V curve for Silicon-Carbon Composite 3, wherein the novel peaks in Regime I and Regime VI are evident, in comparison to Silicon-Carbon Composite 15, Silicon-Carbon Composite 16, and Silicon-Carbon Composite 14, all three of which comprise Z>10 and whose dQ/dV vs V curves are devoid of the any peaks in Regime I and Regime VI.

Without being bound by theory, these novel peaks observed in Regime I and Regime VI relate to the properties of the silicon impregnated into the porous carbon scaffold, i.e., related to the interactions between and among the properties of the porous carbon scaffold, the silicon impregnated into the porous carbon scaffold via CVI, and lithium. In order to provide a quantitative analysis, we herein define the parameter φ, which is calculated as the normalized peak I with respect to peak III as:

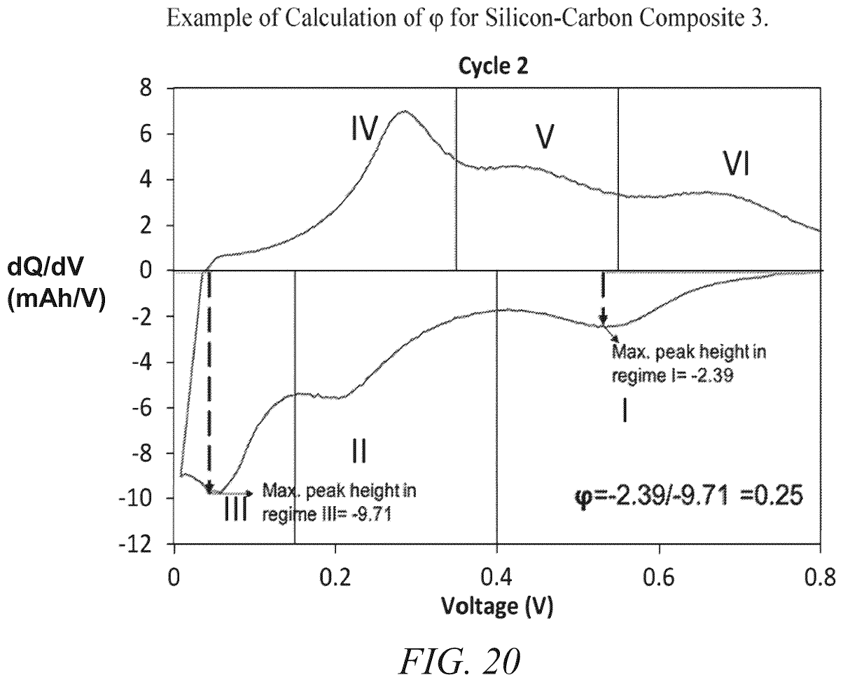

φ=(Max peak height dQ/dV in Regime I)/(Max peak height dQ/dV in Regime III)

where dQ/dV is measured in a half-cell coin cell, and regime I is 0.8V-0.4V and Regime III is 0.15V-0V; the half-cell coin cell is produced as known in the art. If the Si—C sample shows peaks associated with graphite in regime III of the differential curve, it is omitted in favor of Li—Si related phase transition peaks for the calculation of D factor. For this example, the half-cell coin cell includes an anode comprising 60-90% silicon-carbon composite, 5-20% SBR-Na-CMC, and 5-20% Super C45. An example for φ calculation is shown in FIG. 20 for Silicon-Carbon Composite 3. In this instance, the maximum peak height in the regime I is −2.39 and is found at voltage 0.53V. Similarly, maximum peak height in regime III is −9.71 at 0.04V. In this instance, φ can be calculated using the above formula, yielding φ=−2.39/−9.71=0.25. The value of φ was determined from the half-cell coin cell data for the various silicon-carbon composites presented in Example 2. These data are summarized in Table 6.

TABLE 6
Properties of various silicon-carbon materials.

| Silicon- | | | | | | |
|---|---|---|---|---|---|---|
| Carbon | Surface | Si | | Average | | First |
| Composite | Area | content | | CE | | Cycle |
| # | (m²/g) | (%) | Z | (7-20) | φ | Efficiency |
| 1 | 7 | 45.0 | 0.2 | 0.9981 | 0.24 | 76.3 |
| 2 | 7 | 45.4 | 0.6 | 0.9980 | 0.24 | 76.8 |
| 3 | 6 | 45.8 | 0.6 | 0.9975 | 0.25 | 75.5 |
| 4 | 3.06 | 50.1 | 1.0 | 0.9969 | 0.18 | 80.9 |
| 5 | 1.96 | 51.3 | 2.0 | 0.9974 | 0.18 | 80.3 |
| 6 | 140 | 43.1 | 3.2 | 0.9941 | 0.13 | 52.3 |
| 7 | 1.61 | 48.7 | 2.8 | 0.9977 | 0.19 | 79.2 |
| 8 | 2 | 48.5 | 3.0 | 0.9972 | 0.19 | 78.3 |
| 9 | 8 | 46.3 | 0.2 | 0.9976 | 0.20 | 73.3 |
| 10 | 44 | 51.2 | 6.2 | 0.9975 | 0.13 | 78.1 |
| 11 | 94 | 48.9 | 6.2 | 0.9969 | 0.15 | 72.7 |
| 12 | 61 | 52.1 | 10.6 | 0.9869 | 0 | 80.2 |
| 13 | 68.5 | 34.6 | 17.2 | 0.9909 | 0 | 64 |
| 14 | 20 | 74 | 33.5 | 0.9717 | 0 | 85 |
| 15 | 149 | 57.7 | 34.5 | 0.9766 | 0 | 69 |
| 16 | 61.7 | 68.9 | 38.7 | 0.9757 | 0 | 79.3 |
| 17 | 11 | 46.1 | 0.8 | 0.9990 | 0.35 | 82.2 |
| 18 | 11 | 46.7 | 2.0 | 0.9985 | 0.34 | 82.5 |
| | | | | | | (92.1*) |
| 19 | 15.1 | 46.8 | 1.7 | 0.9980 | 0.34 | 79.9 |
| | | | | | | (90.3*) |
| 20 | 4.1 | 47.9 | 4.2 | 0.9953 | 0.34 | 83.3 |
| | | | | | | (92.6*) |
| 21 | 5 | 48.1 | 4.6 | 0.9962 | 0.32 | 82.9 |
| | | | | | | (92.2*) |
| 22 | 5.1 | 44.5 | 0 | ND | ND | ND |
| 23 | 8.4 | 43.6 | 0 | ND | ND | ND |
| 24 | 13.6 | 46.0 | 0.92 | Pending | 0.30 | 81.9 |
| | | | | | | (91.2*) |

ND = not determined;
*These data for first cycle efficiency in parenthesis were measured for voltage window of 5 mV to 1.5 V.

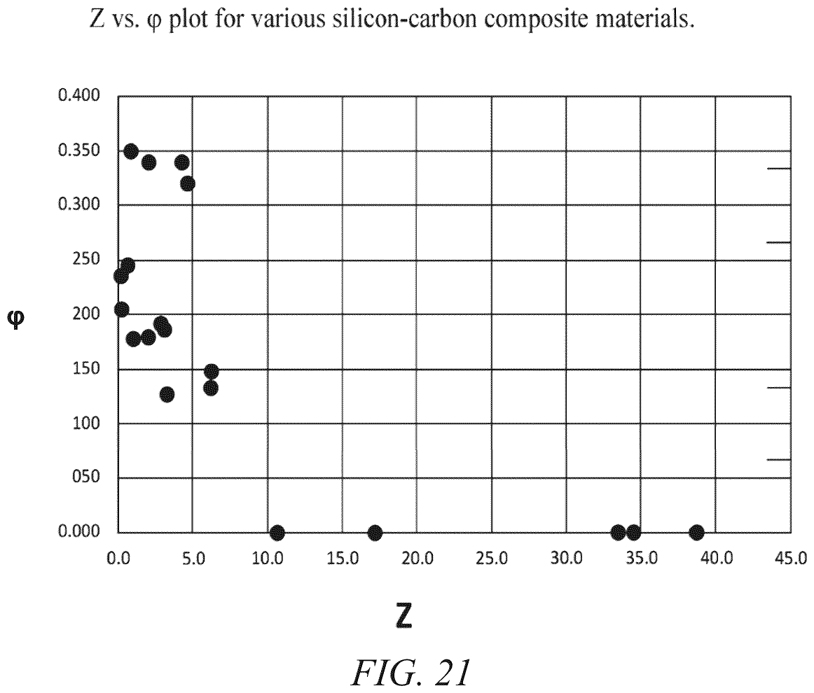

The data in Table 6 reveal an unexpected relationship between decreasing Z and increasing φ. All silicon-carbon composites with Z<10 had φ≥0.13, and all silicon-carbon composites with Z >10 had φ<0.13, indeed, all silicon-carbon composites with where Z>10 had φ=0. This relationship is also evidenced in FIG. 21. Without being bound by theory, silicon materials comprising φ≥0.10, for example φ≥0.13, correspond to a novel form of silicon. Alternatively, silicon materials comprising φ>0 correspond to a novel form of silicon. Without being bound by theory, silicon materials comprising φ>0 are characteristic to silicon material wherein the silicon is amorphous, nano-sized silicon confined within pores, for example pores of a porous carbon scaffold. The silicon-carbon composite material comprising silicon comprising φ≥0.10, for example φ≥0.13, corresponds to a novel silicon-carbon composite material. Alternatively, silicon-carbon composite materials comprising φ>0 corresponds to a novel silicon-carbon composite material.

In certain embodiments, the silicon-carbon composite includes a φ≥0.1, φ≥0.11, φ≥0.12, φ≥0.13, φ≥0.14, φ≥0.15, φ≥0.16, φ≥0.17, φ≥0.18, φ≥0.19, φ≥0.20, φ≥0.24, φ≥0.24, φ≥0.25, φ≥0.30 or φ≥0.35. In some embodiments, φ≥0. In some embodiments, φ≥0.001, φ≥0.01, φ≥0.02, φ≥0.05, φ≥0.1, φ≥0.11, or φ≥0.12.

In certain embodiments, the silicon-carbon composite material includes a Z less than 10 and a carbon scaffold with >70% microporosity, and wherein the silicon-carbon composite also includes 30%-60% silicon, and surface area less than 100 m²/g, and φ≥0.1, for example Z less than 10 and >70% microporosity, and wherein the silicon-carbon composite also includes 30%-60% silicon, and surface area less than 50 m²/g, and φ≥0.1, for example Z less than 10 and >70% microporosity, and wherein the silicon-carbon composite also includes 30%-60% silicon, and surface area less than 30 m²/g, and φ≥0.1, for example Z less than 10 and >70% microporosity, and wherein the silicon-carbon composite also includes 30%-60% silicon, and surface area less than 10 m²/g, and φ≥0.1, for example Z less than 10 and >70% microporosity, and wherein the silicon-carbon composite also includes 30%-60% silicon, and surface area less than 5 m²/g, and φ≥0.1.

In certain embodiments, the silicon-carbon composite material includes a Z less than 10 and a carbon scaffold with >70% microporosity, and wherein the silicon-carbon composite also includes 40%-60% silicon, and surface area less than 100 m²/g, and φ≥0.1, for example Z less than 10 and >70% microporosity, and wherein the silicon-carbon composite also includes 40%-60% silicon, and surface area less than 50 m²/g, and φ≥0.1, for example Z less than 10 and >70% microporosity, and wherein the silicon-carbon composite also includes 40%-60% silicon, and surface area less than 30 m²/g, and φ≥0.1, for example Z less than 10 and >70% microporosity, and wherein the silicon-carbon composite also includes 40%-60% silicon, and surface area less than 10 m²/g, and φ≥0.1, for example Z less than 10 and >70% microporosity, and wherein the silicon-carbon composite also includes 40%-60% silicon, and surface area less than 5 m²/g, and φ≥0.1.

In certain embodiments, the silicon-carbon composite material includes a Z less than 10 and a carbon scaffold with >70% microporosity, and wherein the silicon-carbon composite also includes 30%-60% silicon, and surface area less than 100 m²/g, and φ>0, for example Z less than 10 and >70% microporosity, and wherein the silicon-carbon composite also includes 30%-60% silicon, and surface area less than 50 m²/g, and φ>0, for example Z less than 10 and >70% microporosity, and wherein the silicon-carbon composite also includes 30%-60% silicon, and surface area less than 30 m²/g, and φ>0, for example Z less than 10 and >70% microporosity, and wherein the silicon-carbon composite also includes 30%-60% silicon, and surface area less than 10 m²/g, and φ>0, for example Z less than 10 and >70% microporosity, and wherein the silicon-carbon composite also includes 30%-60% silicon, and surface area less than 5 m²/g, and φ>0.

In certain embodiments, the silicon-carbon composite material includes a Z less than 10 and a carbon scaffold with >70% microporosity, and wherein the silicon-carbon composite also includes 40%-60% silicon, and surface area less than 100 m²/g, and φ>0, for example Z less than 10 and >70% microporosity, and wherein the silicon-carbon composite also includes 40%-60% silicon, and surface area less than 50 m²/g, and φ>0, for example Z less than 10 and >70% microporosity, and wherein the silicon-carbon composite also includes 40%-60% silicon, and surface area less than 30 m²/g, and φ>0, for example Z less than 10 and >70% microporosity, and wherein the silicon-carbon composite also includes 40%-60% silicon, and surface area less than 10 m²/g, and φ>0, for example Z less than 10 and >70% microporosity, and wherein the silicon-carbon composite also includes 40%-60% silicon, and surface area less than 5 m²/g, and φ>0.

In certain embodiments, the silicon-carbon composite material includes a Z less than 10 and a carbon scaffold with >80% microporosity, and wherein the silicon-carbon composite also includes 30%-60% silicon, and surface area less than 100 m²/g, and φ>0.1, for example Z less than 10 and >80% microporosity, and wherein the silicon-carbon composite also includes 30%-60% silicon, and surface area less than 50 m²/g, and φ≥0.1, for example Z less than 10 and >80% microporosity, and wherein the silicon-carbon composite also includes 30%-60% silicon, and surface area less than 30 m²/g, and φ≥0.1, for example Z less than 10 and >80% microporosity, and wherein the silicon-carbon composite also includes 30%-60% silicon, and surface area less than 10 m²/g, and φ≥0.1, for example Z less than 10 and >80% microporosity, and wherein the silicon-carbon composite also includes 30%-60% silicon, and surface area less than 5 m²/g, and @≥0.1.

In certain embodiments, the silicon-carbon composite material includes a Z less than 10 and a carbon scaffold with >80% microporosity, and wherein the silicon-carbon composite also includes 40%-60% silicon, and surface area less than 100 m²/g, and φ≥0.1, for example Z less than 10 and >80% microporosity, and wherein the silicon-carbon composite also includes 40%-60% silicon, and surface area less than 50 m²/g, and φ≥0.1, for example Z less than 10 and >80% microporosity, and wherein the silicon-carbon composite also includes 40%-60% silicon, and surface area less than 30 m²/g, and φ≥0.1, for example Z less than 10 and >80% microporosity, and wherein the silicon-carbon composite also includes 40%-60% silicon, and surface area less than 10 m²/g, and φ≥0.1, for example Z less than 10 and >80% microporosity, and wherein the silicon-carbon composite also includes 40%-60% silicon, and surface area less than 5 m²/g, and φ≥0.1.

In certain embodiments, the silicon-carbon composite material includes a Z less than 10 and a carbon scaffold with >80% microporosity, and wherein the silicon-carbon composite also includes 30%-60% silicon, and surface area less than 100 m²/g, and φ>0, for example Z less than 10 and >80% microporosity, and wherein the silicon-carbon composite also includes 30%-60% silicon, and surface area less than 50 m²/g, and φ>0, for example Z less than 10 and >80% microporosity, and wherein the silicon-carbon composite also includes 30%-60% silicon, and surface area less than 30 m²/g, and φ>0, for example Z less than 10 and >80% microporosity, and wherein the silicon-carbon composite also includes 30%-60% silicon, and surface area less than 10 m²/g, and φ>0, for example Z less than 10 and >80% microporosity, and wherein the silicon-carbon composite also includes 30%-60% silicon, and surface area less than 5 m²/g, and @>0.

In certain embodiments, the silicon-carbon composite material includes a Z less than 10 and a carbon scaffold with >80% microporosity, and wherein the silicon-carbon composite also includes 40%-60% silicon, and surface area less than 100 m²/g, and φ>0, for example Z less than 10 and >80% microporosity, and wherein the silicon-carbon composite also includes 40%-60% silicon, and surface area less than 50 m²/g, and φ>0, for example Z less than 10 and >80% microporosity, and wherein the silicon-carbon composite also includes 40%-60% silicon, and surface area less than 30 m²/g, and φ>0, for example Z less than 10 and >80% microporosity, and wherein the silicon-carbon composite also includes 40%-60% silicon, and surface area less than 10 m²/g, and φ>0, for example Z less than 10 and >80% microporosity, and wherein the silicon-carbon composite also includes 40%-60% silicon, and surface area less than 5 m²/g, and φ>0.

In certain embodiments, the silicon-carbon composite material includes a Z less than 10 and a carbon scaffold with >90% microporosity, and wherein the silicon-carbon composite also includes 30%-60% silicon, and surface area less than 100 m²/g, and φ≥0.1, for example Z less than 10 and >90% microporosity, and wherein the silicon-carbon composite also includes 30%-60% silicon, and surface area less than 50 m²/g, and φ≥0.1, for example Z less than 10 and >90% microporosity, and wherein the silicon-carbon composite also includes 30%-60% silicon, and surface area less than 30 m²/g, and φ≥0.1, for example Z less than 10 and >90% microporosity, and wherein the silicon-carbon composite also includes 30%-60% silicon, and surface area less than 10 m²/g, and φ≥0.1, for example Z less than 10 and >90% microporosity, and wherein the silicon-carbon composite also includes 30%-60% silicon, and surface area less than 5 m²/g, and φ≥0.1.

In certain embodiments, the silicon-carbon composite material includes a Z less than 10 and a carbon scaffold with >90% microporosity, and wherein the silicon-carbon composite also includes 40%-60% silicon, and surface area less than 100 m²/g, and φ>0.1, for example Z less than 10 and >90% microporosity, and wherein the silicon-carbon composite also includes 40%-60% silicon, and surface area less than 50 m²/g, and φ≥0.1, for example Z less than 10 and >90% microporosity, and wherein the silicon-carbon composite also includes 40%-60% silicon, and surface area less than 30 m²/g, and φ≥0.1, for example Z less than 10 and >90% microporosity, and wherein the silicon-carbon composite also includes 40%-60% silicon, and surface area less than 10 m²/g, and φ≥0.1, for example Z less than 10 and >90% microporosity, and wherein the silicon-carbon composite also includes 40%-60% silicon, and surface area less than 5 m²/g, and φ≥0.1.

In certain embodiments, the silicon-carbon composite material includes a Z less than 10 and a carbon scaffold with >90% microporosity, and wherein the silicon-carbon composite also includes 30%-60% silicon, and surface area less than 100 m²/g, and φ>0, for example Z less than 10 and >90% microporosity, and wherein the silicon-carbon composite also includes 30%-60% silicon, and surface area less than 50 m²/g, and φ>0, for example Z less than 10 and >90% microporosity, and wherein the silicon-carbon composite also includes 30%-60% silicon, and surface area less than 30 m²/g, and φ>0, for example Z less than 10 and >90% microporosity, and wherein the silicon-carbon composite also includes 30%-60% silicon, and surface area less than 10 m²/g, and φ>0, for example Z less than 10 and >90% microporosity, and wherein the silicon-carbon composite also includes 30%-60% silicon, and surface area less than 5 m²/g, and φ>0.

In certain embodiments, the silicon-carbon composite material includes a Z less than 10 and a carbon scaffold with >90% microporosity, and wherein the silicon-carbon composite also includes 40%-60% silicon, and surface area less than 100 m²/g, and φ>0, for example Z less than 10 and >90% microporosity, and wherein the silicon-carbon composite also includes 40%-60% silicon, and surface area less than 50 m²/g, and φ>0, for example Z less than 10 and >90% microporosity, and wherein the silicon-carbon composite also includes 40%-60% silicon, and surface area less than 30 m²/g, and φ>0, for example Z less than 10 and >90% microporosity, and wherein the silicon-carbon composite also includes 40%-60% silicon, and surface area less than 10 m²/g, and φ>0, for example Z less than 10 and >90% microporosity, and wherein the silicon-carbon composite also includes 40%-60% silicon, and surface area less than 5 m²/g, and φ>0.

In certain embodiments, the silicon-carbon composite material includes a Z less than 10 and a carbon scaffold with >95% microporosity, and wherein the silicon-carbon composite also includes 30%-60% silicon, and surface area less than 100 m²/g, and φ≥0.1, for example Z less than 10 and >95% microporosity, and wherein the silicon-carbon composite also includes 30%-60% silicon, and surface area less than 50 m²/g, and φ≥0.1, for example Z less than 5 and >95% microporosity, and wherein the silicon-carbon composite also includes 30%-60% silicon, and surface area less than 30 m²/g, and φ≥0.1, for example Z less than 10 and >95% microporosity, and wherein the silicon-carbon composite also includes 30%-60% silicon, and surface area less than 10 m²/g, and φ≥0.1, for example Z less than 10 and >95% microporosity, and wherein the silicon-carbon composite also includes 30%-60% silicon, and surface area less than 5 m²/g, and φ≥0.1.

In certain embodiments, the silicon-carbon composite material includes a Z less than 10 and a carbon scaffold with >95% microporosity, and wherein the silicon-carbon composite also includes 40%-60% silicon, and surface area less than 100 m²/g, and φ≥0.1, for example Z less than 10 and >95% microporosity, and wherein the silicon-carbon composite also includes 40%-60% silicon, and surface area less than 50 m²/g, and φ≥0.1, for example Z less than 10 and >95% microporosity, and wherein the silicon-carbon composite also includes 40%-60% silicon, and surface area less than 30 m²/g, and φ≥0.1, for example Z less than 10 and >95% microporosity, and wherein the silicon-carbon composite also includes 40%-60% silicon, and surface area less than 10 m²/g, and φ≥0.1, for example Z less than 10 and >95% microporosity, and wherein the silicon-carbon composite also includes 40%-60% silicon, and surface area less than 5 m²/g, and φ≥0.1.

In certain embodiments, the silicon-carbon composite material includes a Z less than 10 and a carbon scaffold with >95% microporosity, and wherein the silicon-carbon composite also includes 30%-60% silicon, and surface area less than 100 m²/g, and φ≥0.1, for example Z less than 10 and >95% microporosity, and wherein the silicon-carbon composite also includes 30%-60% silicon, and surface area less than 50 m²/g, and φ≥0.1, for example Z less than 10 and >95% microporosity, and wherein the silicon-carbon composite also includes 30%-60% silicon, and surface area less than 30 m²/g, and φ≥0.1, for example Z less than 10 and >95% microporosity, and wherein the silicon-carbon composite also includes 30%-60% silicon, and surface area less than 10 m²/g, and φ≥0.1, for example Z less than 10 and >95% microporosity, and wherein the silicon-carbon composite also includes 30%-60% silicon, and surface area less than 5 m²/g, and φ≥0.1.

In certain embodiments, the silicon-carbon composite material includes a Z less than 10 and a carbon scaffold with >95% microporosity, and wherein the silicon-carbon composite also includes 40%-60% silicon, and surface area less than 100 m²/g, and φ>0, for example Z less than 10 and >95% microporosity, and wherein the silicon-carbon composite also includes 40%-60% silicon, and surface area less than 50 m²/g, and φ>0, for example Z less than 10 and >95% microporosity, and wherein the silicon-carbon composite also includes 40%-60% silicon, and surface area less than 30 m²/g, and φ>0, for example Z less than 10 and >95% microporosity, and wherein the silicon-carbon composite also includes 40%-60% silicon, and surface area less than 10 m²/g, and φ>0, for example Z less than 10 and >95% microporosity, and wherein the silicon-carbon composite also includes 40%-60% silicon, and surface area less than 5 m²/g, and φ>0.

Example 4. Particle size distribution for various carbon scaffold materials. The particle size distribution for the various carbon scaffold materials was determined by using a laser diffraction particle size analyzer as known in the art. Table 7 presented the data, specifically the Dv1, Dv10, Dv50, Dv90, and Dv100.

TABLE 7
Properties of various carbon scaffold materials.

| Carbon | |
|---|---|
| Scaffold # | Particle Size Characteristics |
| 1 | Dv1 = 1.2 μm, Dv10 = 2.5 μm, Dv50 = 6.9 μm, |
| | Dv90 = 11.5 μm, Dv100 = 20.1 μm |
| 2 | Dv1 = 1.09, Dv10 = 3.4 μm, Dv50 = 7.67 μm, |
| | Dv90 = 13.3 μm, Dv100 = 17.8 μm |
| 4 | Dv1 = 0.81, Dv10 = 1.9 μm, Dv50 = 6.4 μm, |
| | Dv90 = 16.6 μm, Dv100 = 26.5 μm |
| 5 | Dv1 = 0.62, Dv10 = 1.1 μm, Dv50 = 4.2 μm, |
| | Dv90 = 15.8 μm, Dv100 = 29.8 μm |
| 8 | Dv1 = 1.3, Dv10 = 3.7 μm, Dv50 = 16 μm, |
| | Dv90 = 35.2 μm, Dv100 = 50.7 μm |
| 9 | Dv1 =1.2 μm, Dv10 = 2.7 μm, Dv50 = 7.6 μm, |
| | Dv90 = 12.3 μm, Dv100 = 20.7 μm |
| 10 | Dv1 = 1.09 μm, Dv10 = 2 μm, Dv50 = 6.8 μm, |
| | Dv90 = 12.6 μm, Dv100 = 19.8 μm |
| 11 | Dv1 = 1.3 μm, Dv10 = 2.7 μm, Dv50 = 7.7 μm, |
| | Dv90 = 12.9 μm, Dv100 = 22.7 μm |

Example 5. Effect of CVI process variables on fractional conversion of silicon-containing gas into elemental silicon for production for various silicon-composite materials. Table 8 presents several key CVI process parameters employed for producing the various silicon-carbon materials. For these examples, two reactor types were employed, static bed (SB) type, wherein the bed of porous carbon scaffold is fixed and resides within the heated zone of the reactor, and a horizontally moving bed (HM B), wherein the bed of porous carbon is horizontally traversed through the hot zone. Silicon-Carbon Composite Sample 4, Silicon-Carbon Composite Sample 5, Silicon-Carbon Composite Sample 7, and Silicon-Carbon Composite Sample 8 were produced employing the HM B configuration, and all other Silicon-Carbon Composite Samples listed in Table 8 were produced employing the SB configuration. Other reactor types are envisioned. In other embodiments, the CVI reactor type can be varied, for example the CVI reactor can be a vibro-thermal assisted CVI (VTA-CVI) reactor. In other embodiments, the CVI reactor type can be a convection-thermal assisted CVI (CTA-CVI) reactor. In other embodiments, the CVI reactor type can be a rotating CVI kiln. In other embodiments, the CVI reactor type can be a fluidized bed CVI (FB-CVI) reactor. In the current Example, the CVI process was carried out as a batch process with a of between 1 and 6 hours. In other embodiments, the CVI process can be run as a semi-batch process. In certain other embodiments, the CVI process can be run as a continuous process.

TABLE 8
CVI Process data for producing various silicon-carbon materials.

| | | | | Carbon | Y_{CVI} | |
|---|---|---|---|---|---|---|
| Silicon- | | | | Scaffold | ((mol | |
| Carbon | CVI | Conc. | | Bed | silicon/h)/ | |
| Composite | Temp | Silane | Diluent | Loading | mol carbon | X_{Si} |
| # | (° C.) | (%) | Gas | (g/cm²) | scaffold) | (%) |
| 1 | 450 | 10 | H2 | 0.0081 | 2.90 | 10 |
| 2 | 450 | 30 | H2 | 0.0156 | 16.83 | 8.5 |
| 3 | 450 | 40 | H2 | 0.0158 | 22.74 | 7.5 |
| 4 | 525 | 1.25 | N2 | 0.0078 | 0.37 | 64 |
| 5 | 525 | 1.25 | N2 | 0.0078 | 0.37 | 63 |
| 6 | 450 | 1.25 | N2 | 0.0077 | 1.07 | 43 |
| 7 | 525 | 1.25 | N2 | 0.0078 | 0.37 | 66 |
| 8 | 525 | 1.25 | N2 | 0.0078 | 0.37 | 65 |
| 9 | 450 | 10 | N2 | 0.0079 | 2.83 | 10 |
| 10 | 450 | 1.25 | N2 | 0.0039 | 2.11 | 25 |
| 11 | 450 | 1.25 | N2 | 0.0056 | 1.48 | 35 |
| 12 | 450 | 1.25 | N2 | 0.0039 | 2.11 | 22 |
| 13 | 450 | 1.25 | N2 | 0.0078 | 1.07 | 37 |
| 14 | 450 | 1.25 | N2 | 0.0039 | 2.14 | 17 |
| 15 | 450 | 1.25 | N2 | 0.0059 | 1.41 | 22 |
| 16 | 450 | 1.25 | N2 | 0.0039 | 2.14 | 18 |
| 17 | 430 | 40 | H2 | 0.1684 | 0.28 | 64.7 |
| 18 | 430 | 40 | H2 | 0.1688 | 0.28 | 66.4 |
| 19 | 430 | 40 | H2 | 0.1769 | 0.27 | 69.9 |
| 20 | 400 | 100 | None | 0.5434 | 0.27 | 59.8 |
| 21 | 420 | 100 | None | 0.3026 | 0.12 | 85.2 |
| 22 | 420 | 100 | None | 0.168 | 0.28 | 88.9 |
| 23 | 420 | 100 | None | 0.164 | 0.28 | 91.4 |
| 24 | 375 | Varied* | N2 | 0.375 | 0.11 | 73.7 |

*For this sample, the silane flow rate was varied, therefore, in this case Y_{CVI} is calculated as the overall mol silane per hour, i.e., calculated as the total mol of silane delivered to the CVI reactor divided by the total CVI reaction time.

As presented in Table 8, for samples produced per this example, the CVI temperature was varied from 400° C. to 525° C. Other temperature ranges can be employed for the CVI process, for example from 350° C. to 550° C., for example from 350° C. to 500° C., for example from 350° C. to 450° C., for example from 375° C. to 450° C., for example from 380° C. to 450° C., for example from 385° C. to 450° C., for example from 390° C. to 450° C.

Also presented in Table 8, for samples produced per this example, the silicon-containing precursor gas was silane, and the concentration of silane as the mass fraction of the total gas composition was varied from 1.25% to 100%. For samples where the silane gas was mixed with a diluent gas, the diluent gas was varied, either hydrogen (H2) or nitrogen (N2). Other diluent gases are envisioned, for example argon.

The CVI process may be carried out where the gas introduced into the CVI reactor includes 100% silane. Alternatively, gas introduced into the CVI reactor includes less than 100% silane, and also includes a diluent gas comprising hydrogen, nitrogen, argon, or combinations thereof.

Also presented in Table 8, for samples produced per this example, the areal loading of the starting carbon scaffold material within the bed was varied, from 0.0039 g/cm² to 0.5434 g/cm². In other envisioned embodiments, the areal loading of the carbon scaffold material within the bed can be varied, for example from 0.001 g/cm² to 10 g/cm². In other embodiments, the areal loading of the carbon scaffold material within the bed can be varied, for example from 1 g/cm² to 5 g/cm². In other envisioned embodiments, the areal loading of the carbon scaffold material within the bed can be varied, for example from 5 g/cm² to 10 g/cm². In other envisioned embodiments, the areal loading of the carbon scaffold material within the bed can be greater than 10 g/cm².

Alternatively, the areal loading of the starting carbon scaffold material within the bed can vary from 0.0001 to g/cm² to 1 g/cm². For example, the areal loading of the starting carbon scaffold material within the bed can vary from 0.001 to g/cm² to 1 g/cm², or from 0.002 to g/cm² to 1 g/cm², or from 0.003 to g/cm² to 1 g/cm², or from 0.004 to g/cm² to 1 g/cm², or from 0.005 to g/cm² to 1 g/cm². In some embodiments, the areal loading of the starting carbon scaffold material within the bed can vary from 0.001 g/cm² to 1 g/cm².

Also presented in Table 8, for samples produced per this example, the silane flow rate into the CVI reactor can be normalized to the carbon scaffold. Thus, the carbon scaffold normalized silane flow rate can vary. Since one mol of silane gas comprise one mol of silicon, it can also be described that the carbon scaffold normalized silicon flow rate can be varied. This process parameter can be expressed as:

$${Y}_{CVI} = \frac{mol silicon introduced into the CVI reactor per hour}{mol carbon scaffold in the CVI reactor}$$

In the current example, since the silicon containing gas employed for the CVI process is silane, and each mol of silane includes one mol of silicon, the above equation can be alternatively expressed as:

$${Y}_{CVI} = \frac{mol silane per hour}{mol carbon scaffold in the CVI reactor}$$

A surprising and unexpected result relates to the utilization of the silane gas during CVI processing to prepare the silicon-carbon composite. This utilization as a percentage can be defined as:

$${X}_{Si} = 100 \times \frac{mol silicon in the silicon - carbon composite}{mol silicon feedstock}$$

Wherein the mol silicon in the silicon-carbon composite is determined after CVI processing is completed and from the % silicon in the silicon-carbon composite as determined by TGA. Also, for this determination, the mole silicon feedstock is the total mol of silicon introduced into the CV I reactor in for form of silicon containing gas for the duration of CVI processing to convert the porous carbon scaffold and the silicon containing gas into the silicon-carbon composite. For the embodiment wherein the silicon containing gas is silane, there is 1 mol silicon per mol silane thus:

$${X}_{Si} = 100 \times \frac{mol silicon in the silicon - carbon composite}{mol silicon feedstock}$$

In certain embodiments, the silane flow rate is kept constant for the duration of the CVI reaction. In this case, the mol silane per hour used to calculate Y_{CVI} is the molar silane flow rate in the units of mol/h. In some embodiments, the silane flow is varied, for example in a stepwise fashion, and/or as a ramp. In some embodiments, the silane flow rate at the beginning and end of the CVI reaction duration are lower. In a case where the flow rate has been varied, Y_{CVI} is calculated as the overall mol silane per hour, for instance is calculated as the total mol of silane delivered to the CVI reactor divided by the total CVI reaction time.

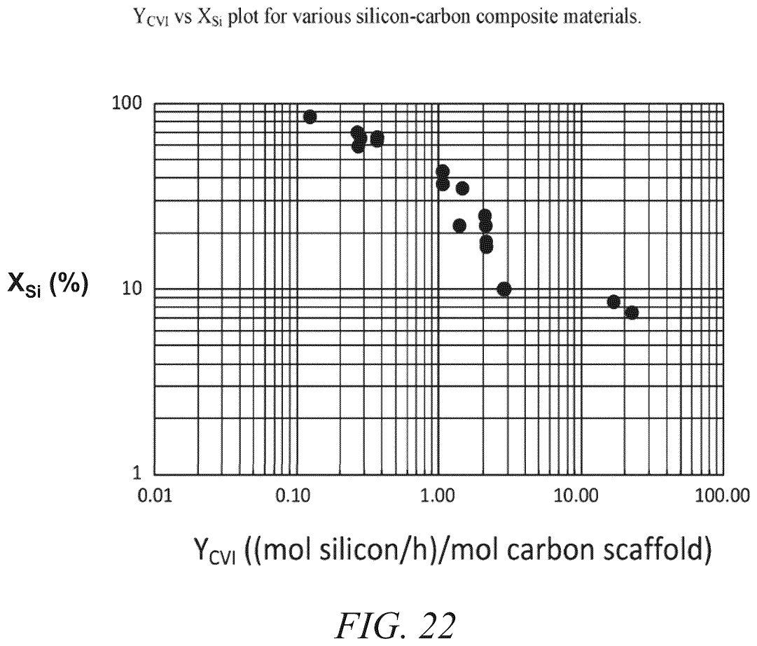

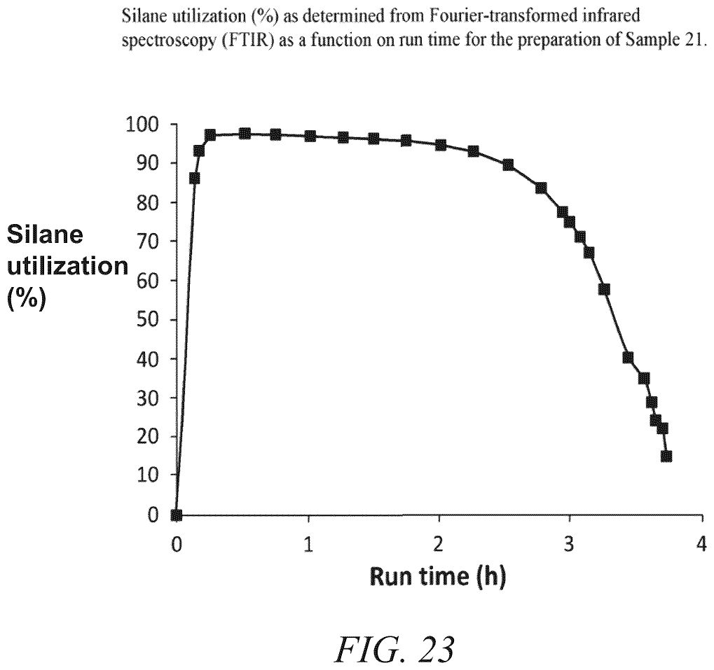

The data for X_{Si} are included in Table 8. As can be seen, X_{Si} increases dramatically as Y_{CVI} decreases (see FIG. 22). In some embodiments for employing CVI to produce the silicon-carbon composite, Y_{CVI}<1 and X_{Si}>50%. In an embodiment for employing CVI to produce the silicon-carbon composite, Y_{CVI}<0.5 and X_{Si}>50%. In a further embodiment for employing CVI to produce the silicon-carbon composite, Y_{CVI}<0.4 and X_{Si}>60%. In a further embodiment for employing CVI to produce the silicon carbon composite, Y_{CVI}<0.3 and X_{Si}>70%. In a further embodiment for employing CVI to produce the silicon carbon composite, Y_{CVI}<0.2 and X_{Si}>70%. In a further embodiment for employing CVI to produce the silicon carbon composite, Y_{CVI}<0.3 and X_{Si}>80%. In a further embodiment for employing CVI to produce the silicon carbon composite, Y_{CVI}<0.2 and X_{Si}>80%. In a further embodiment for employing CVI to produce the silicon carbon composite, Y_{CVI}<0.3 and X_{Si}>85%. In a further embodiment for employing CVI to produce the silicon carbon composite, Y_{CVI}<0.2 and X_{Si}>85%. In a further embodiment for employing CVI to produce the silicon carbon composite, Y_{CVI}<0.3 and X_{Si}>90%. In a further embodiment for employing CVI to produce the silicon carbon composite, Y_{CVI}<0.2 and X_{Si}>90%. In a further embodiment for employing CVI to produce the silicon carbon composite, Y_{CVI}<0.3 and X_{Si}>95%. In a further embodiment for employing CVI to produce the silicon carbon composite, Y_{CVI}<0.2 and X_{Si}>95%. In a further embodiment for employing CVI to produce the silicon carbon composite, Y_{CVI}<0.2 and X_{Si}>99%. In a further embodiment for employing CVI to produce the silicon carbon composite, Y_{CVI}<0.1 and X_{Si}>90%. In a further embodiment for employing CVI to produce the silicon carbon composite, Y_{CVI}<0.1 and X_{Si}>95%. In a further embodiment for employing CVI to produce the silicon carbon composite, Y_{CVI}<0.1 and X_{Si}>99%. In a further embodiment for employing CVI to produce the silicon carbon composite, Y_{CVI}<0.05 and X_{Si}>90%. In a embodiment for employing CVI to produce the silicon carbon composite, Y_{CVI}<0.05 and X_{Si}>95%. In a further embodiment for employing CVI to produce the silicon carbon composite, Y_{CVI}<0.05 and X_{Si}>99%. In a further embodiment for employing CVI to produce the silicon carbon composite, Y_{CVI}<0.01 and X_{Si}>90%. In a further embodiment for employing CVI to produce the silicon carbon composite, Y_{CVI}<0.01 and X_{Si}>95%. In a further embodiment for employing CVI to produce the silicon carbon composite, Y_{CVI}<0.01 and X_{Si}>99%.

Example 6. In-line process monitoring of silane utilization during CVI processing as determined from Fourier-transformed infrared (FTIR) spectroscopy. Fourier-transformed infrared (FTIR) spectroscopy is a suitable method for quantitation of concentration of gas in the gas phase for silane gas. To this end, for the preparation of Silicon-Carbon Composite 21, the gas exiting the reactor was routed into a gas tight FTIR cell within the FTIR spectrophotometer. The % silane concentration exiting the reactor, i.e., concentration of silane exiting the reactor as a percentage of the silane concentration entering the reactor, was quantitated by determining the peak height at 979 cm-1 in the FTIR spectrum for the gas exiting the reactor, and dividing that value by the peak height at 979 cm-1 in the FTIR spectrum for the control, namely unreacted silane gas, and multiplying said value by 100 to convert into percentage. The % silane utilization was then calculated as 100 minus the % silane concentration exiting the reactor. FIG. 24 depicts the in-line process data for % silane utilization as a function of time for preparation of Sample 21. As can be seen, the peak utilization is 98%. Without being bound by theory, based on the analysis from the previous example, the silane flow rate during the initial and final CVI reaction phases can be modulated, i.e., reduced, in order to increase the silane utilization during these phases. In this fashion, X_{Si} can be further increased, for example X_{Si} greater than 85%, or X_{Si} greater than 90%, or X_{Si} greater than 95%, or X_{Si} greater than or equal to 98%. Without being bound by theory, these data also demonstrate the feasibility of conducting the CVI processing in a continuous reactor wherein it is possible to achieve X_{Si} greater than or equal to 98%.

Example 7. CVI Processes Comprising Recycle or Recycle with Purge Stream. The process to create the silicon-carbon composite particles may comprise a recycle stream. Accordingly, the gas exiting the CVI reactor may contain unreacted silane gas, hydrogen gas (created as a result of consumed silane), and diluent gas (if employed) and this gas stream may be re-introduced as one or more feed streams back into the CVI reactor. In certain embodiments, the CVI reactor includes multiple zones, and the silane recycle stream can be fed as one or more feed streams into one or more zones of the CVI reactor. In certain embodiments, the recycle stream includes a purge stream. Accordingly, any hydrogen or diluent gas present in the recycle stream can be separated from the silane present in the recycle stream, for example, by gas separation techniques such as distillation or membrane gas separation. Employing such a recycle stream can further increase net silane utilization, resulting in X_{Si} greater than 50%, for example greater than 60%, for example greater than 70%, for example greater than 85%, for example greater than 90%, for example greater than 95%, for example greater than 98%, for example greater than 99%.

Example 8. CVI performed on large non-agglomerated carbon particles. Poor homogeneity and low silicon content was discovered when using large non-agglomerated carbon particles (>1 mm) Silane diffusion gradients become problematic as particle size was increased. Also, post-milling of the Si—C composite material resulted in aggressive self-heating as a result of oxidation. See Table 9.

TABLE 9
CVI process data using large non-agglomerated carbon particles.

| | | Si—C | | |
|---|---|---|---|---|
| | | specific | | |
| | | surface | | |
| | Carbon PV | area | Si—C PV | TGA wt % |
| Sample | cm³/g | (SSA) | cm³/g | Si |
| Granular (>1 | 0.624 | 439 | 0.378 | 18% |
| mm) | | | | |
| Dv50 = 101 μm | 0.612 | 164 | 0.122 | 33% |
| Dv50 = 28 μm | — | 103 | 0.08 | 35% |

### Example 9. CVI Performed on Agglomerated Carbon Particles

Referring to Table 10, samples A, B, and C used binders methyl cellulose, polyvinyl alcohol, and carboxyl methyl cellulose, respectively. Samples A, B, and C produced compact semi-spherical agglomerations. Agglomerated particle size ranged between a few millimeters to a couple centimeters in diameter. Texture remained hard after CVI and CVP processes. Also, no change in agglomeration sizes were noticed. After CVI no heat up of the agglomerated Si—C composite occurred when exposed to air as well no heat up when a diminution step was conducted.

TABLE 10

| | Post | Agglomorated | Post- | | | | | |
|---|---|---|---|---|---|---|---|---|
| | CVI | Carbon | Process | | | Water | First | Max |
| | heat up? | SSA | SSA | Silicon | Z | Gassing | Cycle | Q |
| Sample | (Y/N) | (m²/g) | (m²/g) | (wt %) | (%) | (ml/g) | Efficiency | (mAh/g) |
| A1 (Pre- | N | 1544 | 6.72 | 48.9 | 1.88 | 9.0 | | |
| Diminution) | | | | | | | | |
| A2 (Post- | N | | 6.58 | 48.6 | 3.41 | 13.2 | 92.0 | 1915.0 |
| Diminution) | | | | | | | | |
| B1 (Pre- | N | 1616 | 6.79 | 49.4 | 2.98 | 14.0 | | |
| Diminution) | | | | | | | | |
| B2 (Post- | N | | 7.06 | 48.9 | 3.25 | 18.7 | #N/A | #N/A |
| Diminution) | | | | | | | | |
| C1 (Pre- | N | 1483 | 7.57 | 48.5 | 2.19 | 14.1 | | |
| Diminution) | | | | | | | | |
| C2 (Post- | N | | 7.82 | 47.6 | 2.32 | 17.9 | #N/A | #N/A |
| Diminution) | | | | | | | | |

Water gassing estimates gas generation from Si—C composite and water reaction. Water gassing methods are well known to those of ordinary skill in the art. Lower water gassing provides better electrode processing and thus better electrochemical performance.

### EXPRESSED EMBODIMENTS

### Embodiment 1

A process for preparing silicon-carbon composite particles comprising providing a porous carbon material comprising a pore volume, wherein the pore volume comprises greater than 70% microporosity, agglomerating the porous carbon material with an agglomerant to produce an agglomerated carbon material, heating the agglomerated carbon material to a temperature from 350° C. to 550° C. and contacting the agglomerated carbon material with a silane feedstock gas to produce the silicon-carbon composite particles.

### Embodiment 2

The process of Embodiment 1, wherein a Dv50 for the agglomerated porous carbon material is greater than a Dv50 of the porous carbon material.

### Embodiment 3

The process of Embodiment 2, wherein the pore volume of the agglomerated porous carbon material comprises volume average particle size (Dv50) of less than 1 cm.

### Embodiment 4

The process of Embodiment 1, wherein agglomerating comprises mixing an immiscible binder with a liquid to produce the agglomerant and combining the porous carbon material with the agglomerant to produce the agglomerated carbon material.

### Embodiment 5

The process of Embodiment 4, wherein the immiscible binder comprises carboxymethylcellulose (CMC).

### Embodiment 6

The process of Embodiment 1, wherein agglomerating comprises dissolving a pre-agglomerant in a liquid to produce the agglomerant and combining the porous carbon material with the agglomerant to produce the agglomerated carbon material.

### Embodiment 7

The process of Embodiment 6, wherein the pre-agglomerant comprises acetone, methanol, benzene, or polyacrylic acid (PAA) and the liquid comprises water or isopropyl alcohol (IPA).

### Embodiment 8

The process of Embodiment 1, wherein the agglomerant is a friction-increasing liquid and agglomerating comprises combining the porous carbon material with the friction-increasing liquid to produce the agglomerated carbon material.

### Embodiment 9

The process of Embodiment 8, wherein the friction-increasing liquid comprises water.

### Embodiment 10

The process of Embodiment 1, wherein the agglomerant is in liquid form and agglomerating comprises combining the porous carbon material with the liquid agglomerant to produce the agglomerated carbon material.

### Embodiment 11

The process of Embodiment 10, wherein the liquid agglomerant comprises novolac polyethylene glycol (PEG) having a molecular weight below 1000.

### Embodiment 12

The process of Embodiment 1, wherein the agglomerant is in at least one of a solid form or has less than a predefined moisture content and further comprising combining the porous carbon material with the agglomerant to produce the agglomerated carbon material.

### Embodiment 13

The process of Embodiment 12, wherein agglomerant comprises polytetrafluoroethylene (PTFE).

### Embodiment 14

The process of Embodiment 1, further comprising applying a passivation coating over at least a portion of the silicon-carbon composite particles.

### Embodiment 15

The process of Embodiment 1, further comprising diminuting the silicon-carbon composite particles to produce silicon-carbon composite particles within a specified size range.

### Embodiment 16

A system for producing silicon-carbon composite particles comprising an agglomerating device configured to agglomerate activated porous carbon material with an agglomerant to produce an agglomerated carbon material and a kiln configured to heat the agglomerated carbon material to a temperature from 350° C. to 550° C. while introducing a silane feedstock gas to perform a chemical vapor infiltration process that produces silicon-carbon composite particles.

### Embodiment 17

The system of Embodiment 16, wherein the kiln comprises one of a vibro-thermal assisted (VTA) reactor, a convection-thermal assisted (CTA) reactor, a rotating kiln, hearth furnace, belt furnace, or a fluidized bed (FB) reactor.

### Embodiment 18

The system of Embodiment 17, wherein the kiln is further configured to perform a batch process between 1 to 6 hours.

### Embodiment 19

The system of Embodiment 17, wherein the kiln is further configured to perform a continuous process.

### Embodiment 20

The system of Embodiment 16, wherein the kiln is further configured to apply a passivation coating over at least a portion of the silicon-carbon composite particles.

### Embodiment 21

The system of Embodiment 16, further comprising a diminution device configured to diminute the silicon-carbon composite particles to produce silicon-carbon composite particles within a specified size range.

From the foregoing it will be appreciated that, although specific embodiments have been described herein for purposes of illustration, various modifications may be made without deviating from the spirit and scope of the invention. Accordingly, the invention is not limited except as by the appended claims.

What is claimed is:

1. A process for preparing silicon-carbon composite particles comprising:
providing a porous carbon material comprising a pore volume, wherein the pore volume comprises greater than 70% microporosity;
agglomerating the porous carbon material with an agglomerant to produce an agglomerated carbon material;
heating the agglomerated carbon material to a temperature from 350° C. to 550° C.; and
contacting the agglomerated carbon material with a silane feedstock gas to produce the silicon-carbon composite particles.

2. The process of claim 1, wherein a Dv50 for the agglomerated porous carbon material is greater than a Dv50 of the provided porous carbon material.

3. The process of claim 2, wherein the agglomerated porous carbon material comprises volume average particle size (Dv50) of less than 1 cm.

4. The process of claim 1, wherein agglomerating comprises:
mixing an immiscible binder with a liquid to produce the agglomerant; and
combining the porous carbon material with the agglomerant to produce the agglomerated carbon material.

5. The process of claim 4, wherein the immiscible binder comprises carboxymethylcellulose (CMC).

6. The process of claim 1, wherein agglomerating comprises:
dissolving a pre-agglomerant in a liquid to produce the agglomerant; and
combining the porous carbon material with the agglomerant to produce the agglomerated carbon material.

7. The process of claim 6, wherein the pre-agglomerant comprises acetone, methanol, benzene, or polyacrylic acid (PAA) and the liquid comprises water or isopropyl alcohol (IPA).

8. The process of claim 1, wherein:
the agglomerant is a friction-increasing liquid; and
agglomerating comprises combining the porous carbon material with the friction-increasing liquid to produce the agglomerated carbon material.

9. The process of claim 8, wherein the friction-increasing liquid comprises water or isopropyl alcohol.

10. The process of claim 1, wherein:
the agglomerant is in liquid form; and
agglomerating comprises combining the porous carbon material with the agglomerant to produce the agglomerated carbon material.

11. The process of claim 10, wherein the liquid agglomerant comprises novolac polyethylene glycol (PEG) having a molecular weight below 1000.

12. The process of claim 1, wherein the agglomerant is in at least one of a solid form or has less than a predefined moisture content; and
further comprising combining the porous carbon material with the agglomerant to produce the agglomerated carbon material.

13. The process of claim 12, wherein agglomerant comprises polytetrafluoroethylene (PTFE).

14. The process of claim 1, further comprising:
applying a passivation coating over at least a portion of the silicon-carbon composite particles.

15. The process of claim 1, further comprising:
diminuting the silicon-carbon composite particles to produce silicon-carbon composite particles within a specified size range.

16. A system for producing silicon-carbon composite particles comprising:
an agglomerating device configured to agglomerate activated porous carbon material with an agglomerant to produce an agglomerated carbon material; and
a kiln configured to heat the agglomerated carbon material to a temperature from 350° C. to 550° C. while introducing a silane feedstock gas to perform a chemical vapor infiltration process that produces silicon-carbon composite particles.

17. The system of claim 16, wherein the kiln comprises one of a vibro-thermal assisted (VTA) reactor, a convection-thermal assisted (CTA) reactor, a rotating kiln, hearth furnace, belt furnace, or a fluidized bed (FB) reactor.

18. The system of claim 17, wherein the kiln is further configured to perform a batch process between 1 to 6 hours.

19. The system of claim 17, wherein the kiln is further configured to perform a continuous process.

20. The system of claim 16, wherein the kiln is further configured to apply a passivation coating over at least a portion of the silicon-carbon composite particles.

21. The system of claim 16, further comprising:
a diminution device configured to diminute the silicon-carbon composite particles to produce silicon-carbon composite particles within a specified size range.
